(19) United States
(12) Patent Application Publication
(10) Pub. No.: US 2025/0313935 A1
(43) Pub. Date: Oct. 9, 2025

(54) DEPOSITION MASK AND METHOD FOR MANUFACTURING THE SAME

(71) Applicant: Samsung Display Co., LTD., Yongin-si (KR)

(72) Inventors: Jun Ho JO, Yongin-si (KR); Jeong Kuk KIM, Yongin-si (KR); Sung Won CHO, Yongin-si (KR)

(21) Appl. No.: 18/959,387

(22) Filed: Nov. 25, 2024

(30) Foreign Application Priority Data
Apr. 4, 2024 (KR) 10-2024-0045799

(51) Int. Cl. C23C 14/04; H10K 59/12

(52) U.S. Cl. CPC C23C 14/042; H10K 59/12

(57) ABSTRACT

A deposition mask includes a mask substrate including a plurality of cell areas, and a cell peripheral area surrounding the cell areas in plan view, a mask membrane overlapping the cell area of the mask substrate, defining a pixel opening, and including a mask shadow, and a mask frame overlapping the cell peripheral area, and including an upper inorganic layer above an upper surface of the mask substrate, and a lower inorganic layer below a lower surface of the mask substrate and having a height that is different than a height of the upper inorganic layer and that is greater than a height of the mask shadow.

### CROSS-REFERENCE TO RELATED APPLICATION

The present application claims priority to, and the benefit of, Korean Patent Application No. 10-2024-0045799, filed on Apr. 4, 2024, in the Korean Intellectual Property Office, the entire disclosure of which is incorporated herein by reference.

### BACKGROUND

### 1. Field

The present disclosure relates to a deposition mask, and a method for manufacturing the same.

### 2. Description of the Related Art

A wearable device that is developed in the form of glasses or a helmet and focuses on a distance close to the user's eyes is being developed. For example, the wearable device may be a head-mounted display (HMD) device or AR glass. Such a wearable device provides a user with an augmented reality (“AR”) screen or a virtual reality (“VR”) screen.

The wearable device, such as the HMD device or the AR glass, may suitably use a display specification of at least 2000 pixels per inch (PPI) to allow the user to use the device for a long time without feeling dizzy. To this end, organic light-emitting diode on silicon (OLEDoS) technology, which is a small organic light-emitting display device with high resolution, is emerging. The OLEDoS is a technology that arranges organic light-emitting diodes (OLEDs) on a semiconductor wafer substrate on which a complementary metal oxide semiconductor (CMOS) is located.

### SUMMARY

Aspects of the present disclosure provide a silicon deposition mask capable of manufacturing a high-resolution display panel, and a method for manufacturing the same.

Aspects of the present disclosure also provide a deposition mask capable of solving damage to the mask caused by stress applied to the mask, and a method for manufacturing the same.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

Details of other embodiments are included in the detailed description and drawings.

According to some embodiments of the present disclosure, a deposition mask includes a mask substrate including a plurality of cell areas, and a cell peripheral area surrounding the cell areas in plan view, a mask membrane overlapping the cell area of the mask substrate, defining a pixel opening, and including a mask shadow, and a mask frame overlapping the cell peripheral area, and including an upper inorganic layer above an upper surface of the mask substrate, and a lower inorganic layer below a lower surface of the mask substrate and having a height that is different than a height of the upper inorganic layer and that is greater than a height of the mask shadow.

The upper inorganic layer may include a first upper inorganic layer in contact with the upper surface of the mask substrate, and a second upper inorganic layer above the first upper inorganic layer, wherein the lower inorganic layer includes a first lower inorganic layer in contact with the lower surface of the mask substrate, and a second lower inorganic layer below the first lower inorganic layer.

The first upper inorganic layer and the first lower inorganic layer may include a same material, wherein the second upper inorganic layer and the second lower inorganic layer include a same material.

The first upper inorganic layer and the first lower inorganic layer may include different respective materials.

The first upper inorganic layer and the first lower inorganic layer may include different respective stress properties.

The mask shadow may include a first mask shadow including a same material as the first upper inorganic layer, and a second mask shadow including a same material as the second upper inorganic layer.

The first mask shadow may include a same material as the first lower inorganic layer, wherein the second mask shadow includes a same material as the second lower inorganic layer.

A height of the first mask shadow may be less than a height of the first lower inorganic layer.

A height of the second mask shadow may be substantially equal to a height of the second upper inorganic layer, wherein the height of the second mask shadow is less than a height of the second lower inorganic layer.

The first mask shadow may include a first surface in a direction away from the second mask shadow, wherein the second mask shadow includes a second surface in a direction away from the first mask shadow, and wherein a width of the first surface in a direction parallel to the mask substrate is less than a width of the second surface.

The first upper inorganic layer may include a first portion and a second portion, wherein a height of the first portion is greater than a height of the second portion.

The mask substrate may include silicon, and has a circular shape in plan view.

The mask shadow may completely surround the pixel opening in plan view, wherein the mask frame completely surrounds the mask shadow in plan view.

The mask substrate may include an edge surface including an edge of the mask substrate, connecting the upper surface of the mask substrate and the lower surface of the mask substrate, being entirely covered by the first upper inorganic layer, and contacting the first upper inorganic layer.

The edge surface may be entirely covered by the second upper inorganic layer.

The lower inorganic layer may further include a third lower inorganic layer below the second lower inorganic layer.

According to some embodiments of the present disclosure, a method for manufacturing a deposition mask includes forming a first inorganic material layer on a mask substrate, forming a second inorganic material layer on the first inorganic material layer, forming a mask membrane by patterning the second inorganic material layer above an upper surface of the mask substrate, forming an opening by removing the first inorganic material layer and the second inorganic material layer below a lower surface of the mask substrate, and by removing a portion of the mask substrate, reducing a height of the first inorganic material layer by etching a portion of the first inorganic material layer overlapping the opening, and forming a pixel opening and a mask shadow.

The forming of the first inorganic material layer may include concurrently forming the first inorganic material layer respectively above and below the upper and lower surfaces of the mask substrate, wherein the forming of the second inorganic material layer includes concurrently forming the second inorganic material layer respectively above and below the upper and lower surfaces of the mask substrate.

The etching of the portion of the first inorganic material layer may be performed in a rear direction of the mask substrate.

In the forming of the mask shadow, the mask shadow may include a first mask shadow including a same material as the first inorganic material layer, and a second mask shadow including a same material as the second inorganic material layer, wherein a height of the first mask shadow is less than a height of the first inorganic material layer below the lower surface of the mask substrate.

According to some embodiments of the present disclosure, an electronic device comprise a display device including a display panel formed using a deposition mask; the mask substrate comprising a plurality of cell areas, and a cell peripheral area surrounding the cell areas in plan view; a mask membrane overlapping the cell area of the mask substrate, defining a pixel opening, and comprising a mask shadow; and a mask frame overlapping the cell peripheral area, and comprising an upper inorganic layer above an upper surface of the mask substrate, and a lower inorganic layer below a lower surface of the mask substrate and having a height that is different than a height of the upper inorganic layer and that is greater than a height of the mask shadow.

According to the deposition mask and the method for manufacturing the same according to the embodiments, the deposition mask for manufacturing the high-resolution display panel may be provided by forming the mask inorganic layer and the mask membrane on the mask substrate. Furthermore, in the deposition mask according to the embodiments, damage caused by stress occurring in the mask may be solved by forming the height of the inorganic layer positioned on the top of the mask to be less than the height of the inorganic layer positioned on the bottom of the mask.

However, the aspects of the embodiments are not restricted to the one set forth herein. The above and other aspects of the embodiments will become more apparent to one of daily skill in the art to which the embodiments pertain by referencing the claims.

### BRIEF DESCRIPTION OF THE DRAWINGS

The above and other aspects of the present disclosure will become more apparent by describing in detail embodiments thereof with reference to the attached drawings, in which:

FIG. 1 is a perspective view illustrating a head-mounted electronic device according to one or more embodiments;

FIG. 2 is an exploded perspective view illustrating an example of the head-mounted electronic device of FIG. 1;

FIG. 3 is a perspective view illustrating a head-mounted electronic device according to one or more embodiments;

FIG. 4 is an exploded perspective view illustrating a display device according to one or more embodiments;

FIG. 5 is a cross-sectional view illustrating an example in which a portion of a display panel according to one or more embodiments is cut;

FIG. 6 is a schematic plan view of a mask according to one or more embodiments;

FIG. 7 is an enlarged plan view of area A of FIG. 6;

FIG. 8 is a cross-sectional view taken along the line X1-X1′ of FIG. 6;

FIG. 9 is an enlarged cross-sectional view of area A of FIG. 8;

FIG. 10 is a cross-sectional view taken along the line X1-X1′ of FIG. 6, as one or more other embodiments;

FIG. 11 is a flowchart describing a method for manufacturing the mask illustrated in FIG. 8;

FIGS. 12 to 23 are process cross-sectional views for describing the method for manufacturing the mask of FIG. 8;

FIG. 24 is a cross-sectional view taken along the line X1-X1′ of FIG. 6, as still one or more other embodiments;

FIG. 25 is a flowchart describing a method for manufacturing the mask illustrated in FIG. 24;

FIGS. 26 to 30 are process cross-sectional views for describing the method for manufacturing the mask of FIG. 24;

FIG. 31 is a cross-sectional view taken along the line X1-X1′ of FIG. 6, as still one or more other embodiments;

FIG. 32 is a flowchart describing a method for manufacturing the mask illustrated in FIG. 31; and

FIGS. 33 to 36 are process cross-sectional views for describing the method for manufacturing the mask of FIG. 31.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

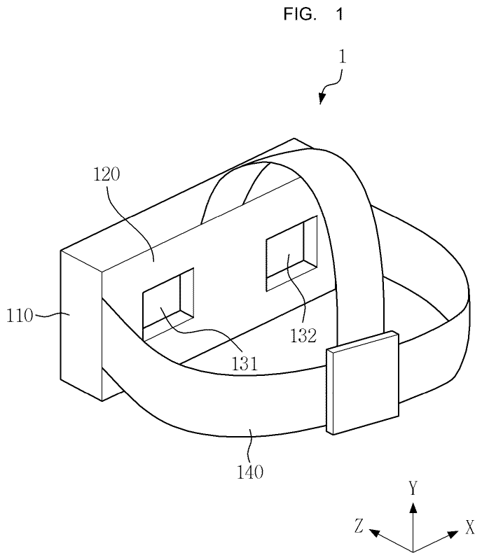

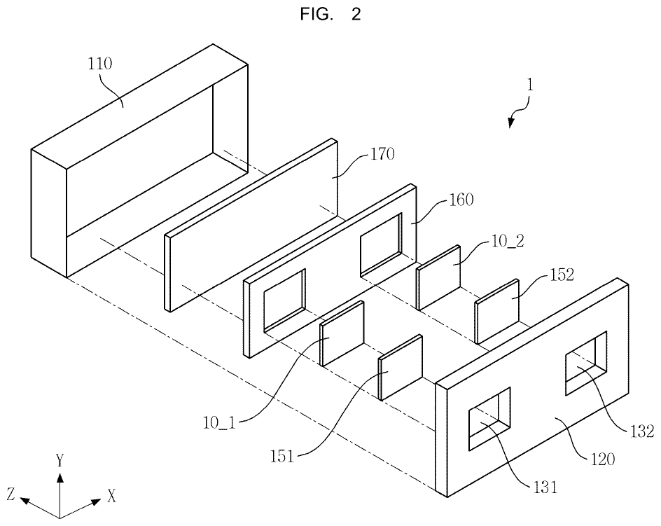

FIG. 1 is a perspective view illustrating a head-mounted electronic device 1 according to one or more embodiments. FIG. 2 is an exploded perspective view illustrating an example of the head-mounted electronic device 1 of FIG. 1.

Referring to FIGS. 1 and 2, a head-mounted electronic device 1 according to one or more embodiments includes a display device accommodating portion 110, an accommodating portion cover 120, a first eyepiece 131, a second eyepiece 132, a head-mounting band 140, a first display device 10_1, a second display device 10_2, a middle frame 160, a first optical member 151, a second optical member 152, a control circuit board 170, and a connector.

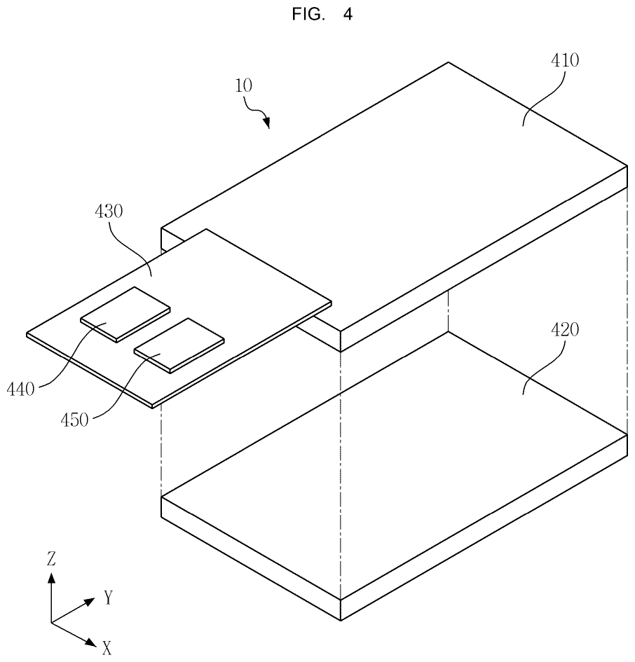

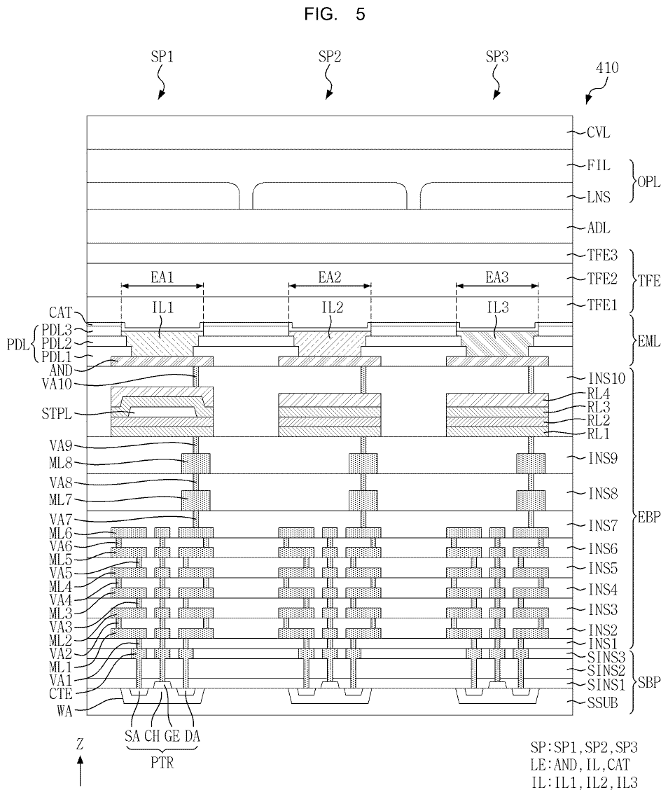

The first display device 10_1 provides an image to a user's left eye, and the second display device 10_2 provides an image to a user's right eye. Each of the first display device 10_1 and the second display device 10_2 is substantially the same as a display device 10 described with reference to FIGS. 4 and 5. Accordingly, descriptions of the first display device 10_1 and the second display device 10_2 will be replaced with descriptions with reference to FIGS. 4 and 5.

The first optical member 151 may be located between the first display device 10_1 and the first eyepiece 131. The second optical member 152 may be located between the second display device 10_2 and the second eyepiece 132. Each of the first optical member 151 and the second optical member 152 may include at least one convex lens.

The middle frame 160 may be located between the first display device 10_1 and the control circuit board 170 and may be located between the second display device 10_2 and the control circuit board 170. The middle frame 160 serves to support and fix the first display device 10_1, the second display device 10_2, and the control circuit board 170.

The control circuit board 170 may be located between the middle frame 160 and the display device accommodating portion 110. The control circuit board 170 may be connected to the first display device 10_1 and the second display device 10_2 through the connector. The control circuit board 170 may convert an image source input from the outside into digital video data DATA, and may transmit the digital video data DATA to the first display device 10_1 and the second display device 10_2 through the connector.

The control circuit board 170 may transmit digital video data DATA corresponding to a left eye image optimized for the user's left eye to the first display device 10_1, and may transmit digital video data DATA corresponding to a right eye image optimized for the user's right eye to the second display device 10_2. Alternatively, the control circuit board 170 may transmit the same digital video data DATA to the first display device 10_1 and the second display device 10_2.

The display device accommodating portion 110 serves to accommodate the first display device 10_1, the second display device 10_2, the middle frame 160, the first optical member 151, the second optical member 152, the control circuit board 170, and the connector. The accommodating portion cover 120 may cover one opened surface of the display device accommodating portion 110. The accommodating portion cover 120 may include a first eyepiece 131 where the user's left eye is located and a second eyepiece 132 where the user's right eye is located. It is illustrated in FIGS. 1 and 2 that the first eyepiece 131 and the second eyepiece 132 are separately located, but the present specification is not limited thereto. The first eyepiece 131 and the second eyepiece 132 may be integrated into one.

The first eyepiece 131 may be aligned with the first display device 10_1 and the first optical member 151, and the second eyepiece 132 may be aligned with the second display device 10_2 and the second optical member 152. Therefore, the user may view an image of the first display device 10_1 magnified as a virtual image by the first optical member 151 through the first eyepiece 131, and may view an image of the second display device 10_2 magnified as a virtual image by the second optical member 152 through the second eyepiece 132.

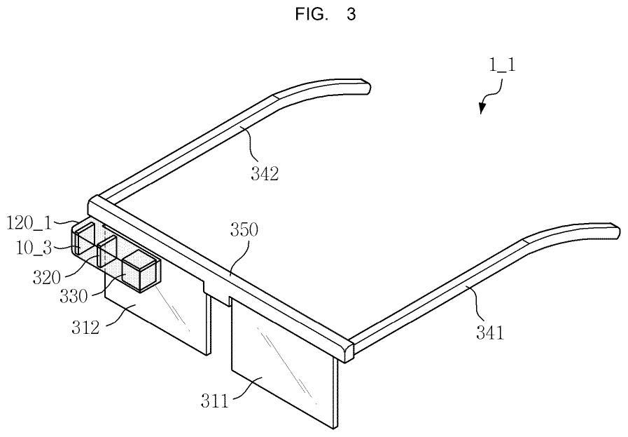

The head-mounting band 140 serves to fix the display device accommodating portion 110 to a user's head so that the first eyepiece 131 and the second eyepiece 132 of the accommodating portion cover 120 are located on the user's left and right eyes, respectively. When the display device accommodating portion 110 is implemented to be lightweight and to have a relatively small size, the head-mounted electronic device 1 may include eyeglass frames as illustrated in FIG. 3 instead of the head-mounting band 140.

In addition, the head-mounted electronic device 1 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, or a Bluetooth module.

FIG. 3 is a perspective view illustrating a head-mounted electronic device 1_1 according to one or more embodiments.

Referring to FIG. 3, a head-mounted electronic device 1_1 according to one or more embodiments may be a glasses-type display device in which a display device accommodating portion 120_1 is implemented in a lightweight and small size. The head-mounted electronic device 1_1 according to one or more embodiments may include a display device 10_3, a left eye lens 311, a right eye lens 312, a support frame 350, eyeglass frame legs 341 and 342, an optical member 320, a light path conversion member 330, and a display device accommodating portion 120_1.

The display device 10_3 illustrated in FIG. 3 is substantially the same as the display device 10 described with reference to FIGS. 4 and 5. Accordingly, descriptions of the first display device 10_1 and the second display device 10_2 will be replaced with descriptions with reference to FIGS. 4 and 5.

The display device accommodating portion 120_1 may include the display device 10_3, the optical member 320, and the light path conversion member 330. As an image displayed on the display device 10_3 is magnified by the optical member 320 and a light path thereof is converted by the light path conversion member 330, the image may be provided to the user's right eye through the right eye lens 312. Accordingly, the user may view an augmented reality image in which a virtual image displayed on the display device 10_3 and a real image viewed through the right eye lens 312 are combined through the right eye.

It is illustrated in FIG. 3 that the display device accommodating portion 120_1 is located at a right distal end of the support frame 350, but the present specification is not limited thereto. For example, the display device accommodating portion 120_1 may be located at a left distal end of the support frame 350, and in this case, the image of the display device 10_3 may be provided to the user's left eye. Alternatively, the display device accommodating portions 120_1 may be located at both the left and right distal ends of the support frame 350. In this case, the user may view the image displayed on the display device 10_3 through both the user's left and right eyes.

FIG. 4 is an exploded perspective view illustrating a display device 10 according to one or more embodiments.

Referring to FIG. 4, a display device 10 according to one or more embodiments is a device that displays a moving image or a still image. The display device 10 according to one or more embodiments may be applied to portable electronic devices, such as a mobile phone, a smart phone, a tablet personal computer (PC), a mobile communication terminal, an electronic notebook, an electronic book, a portable multimedia player (PMP), navigation, and an ultra-mobile PC (UMPC). For example, the display device 10 may be applied to a display unit of a television, a laptop computer, a monitor, a billboard, or the Internet of Things (IoT). Alternatively, the display device 10 may be applied to a smart watch, a watch phone, and a head-mounted display (HMD) for implementing virtual reality and augmented reality.

The display device 10 according to one or more embodiments includes a display panel 410, a heat dissipation layer 420, a circuit board 430, a driving circuit 440, and a power supply circuit 450.

The display panel 410 may be formed in a planar shape similar to a quadrangle. For example, the display panel 410 may have a planar shape similar to a quadrangle having short sides in a first direction DR1 (X-axis direction) and long sides in a second direction DR2 (Y-axis direction) intersecting the first direction DR1 (X-axis direction). In the display panel 410, a corner where the short side in the first direction (X-axis direction) and the long side in the second direction (Y-axis direction) meet each other may be formed at a right angle or may be formed in a round shape so as to have a curvature (e.g., predetermined curvature). The planar shape of the display panel 410 is not limited to the quadrangle, and may be formed similarly to other polygons, circles, or ovals. A planar shape of the display device 10 may follow the planar shape of the display panel 410, but the present specification is not limited thereto.

The display panel 410 includes a display area that displays an image and a non-display area that does not display an image.

The display area includes a plurality of pixels, and each of the plurality of pixels includes a plurality of sub-pixels (SP1, SP2, and SP3 in FIG. 5). The plurality of sub-pixels SP1, SP2, and SP3 include a plurality of pixel transistors. The plurality of pixel transistors may be formed through a semiconductor process and may be located on a semiconductor substrate (SSUB in FIG. 5). For example, the plurality of pixel transistors may be formed of a complementary metal oxide semiconductor (CMOS).

The heat dissipation layer 420 may overlap the display panel 410 in a third direction (Z-axis direction), which is a thickness direction of the display panel 410. The heat dissipation layer 420 may be located on one surface of the display panel 410, for example, a rear surface thereof. The heat dissipation layer 420 serves to dissipate heat generated from the display panel 410. The heat dissipation layer 420 may include a metal layer, such as graphite, silver (Ag), copper (Cu), or aluminum (Al) having high thermal conductivity.

The circuit board 430 may be electrically connected to a plurality of pads PD of a pad area PDA of the display panel 410 by using a conductive adhesive member, such as an anisotropic conductive film. The circuit board 430 may be a flexible printed circuit board or flexible film made of a flexible material. It is illustrated in FIG. 4 that the circuit board 430 is unfolded, but the circuit board 430 may be bent. In this case, one end of the circuit board 430 may be located on the rear surface of the display panel 410. One end of the circuit board 430 may be an opposite end of the other end of the circuit board 430 connected to the plurality of pads PD of the pad area PDA of the display panel 410 by using a conductive adhesive member.

The driving circuit 440 may receive externally supplied digital video data and timing signals. The driving circuit 440 may generate a scan-timing control signal, an emission-timing control signal, and a data-timing control signal for controlling the display panel 410 according to the timing signals.

The power supply circuit 450 may generate a plurality of panel driving voltages according to a power voltage from the outside.

The driving circuit 440 and the power supply circuit 450 may be each formed as an integrated circuit (IC) and attached to one surface of the circuit board 430.

FIG. 5 is a cross-sectional view illustrating an example in which a portion of a display panel 410 according to one or more embodiments is cut. For example, FIG. 5 illustrates a partial cross-sectional structure of a display area including a plurality of sub-pixels (SP1, SP2, and SP3 in FIG. 5).

Referring to FIG. 5, the display panel 410 includes a semiconductor backplane SBP, a light-emitting element backplane EBP, a light-emitting element layer EML, an encapsulation layer TFE, an optical layer OPL, and a cover layer CVL.

The semiconductor backplane SBP includes a semiconductor substrate SSUB including a plurality of pixel transistors PTR, a plurality of semiconductor insulating films covering the plurality of pixel transistors PTR, and a plurality of contact terminals CTE electrically connected to the plurality of pixel transistors PTR, respectively.

The semiconductor substrate SSUB may be a silicon substrate, a germanium substrate, or a silicon-germanium substrate. The semiconductor substrate SSUB may be a substrate doped with first-type impurities. A plurality of well areas WA may be located on an upper surface of the semiconductor substrate SSUB. The plurality of well areas WA may be areas doped with second-type impurities. The second-type impurity may be different from the first-type impurity described above. For example, when the first-type impurity is a p-type impurity, the second-type impurity may be an n-type impurity. Alternatively, when the first-type impurity is an n-type impurity, the second-type impurity may be a p-type impurity.

The semiconductor substrate SSUB may be replaced with a glass substrate or a polymer resin substrate, such as polyimide. In this case, thin film transistors may be located on the glass substrate or the polymer resin substrate. The glass substrate may be a rigid substrate that is not bent, and the polymer resin substrate may be a flexible substrate that may be bent or curved.

Each of the plurality of well areas WA includes a source area SA corresponding to a source electrode of the pixel transistor PTR, a drain area DA corresponding to a drain electrode thereof, and a channel area CH located between the source area SA and the drain area DA.

Each of the source area SA and the drain area DA may be an area doped with first-type impurities. A gate electrode GE of the pixel transistor PTR may overlap the well area WA in the third direction (Z-axis direction). The channel area CH may overlap the gate electrode GE in the third direction (Z-axis direction). The source area SA may be located on one side of the gate electrode GE, and the drain area DA may be located on the other side of the gate electrode GE.

A first semiconductor insulating film SINS1 may be located on the semiconductor substrate SSUB (as used herein, “located on,” “formed on,” or “positioned on” may mean “above” or may mean “below”). The first semiconductor insulating film SINS1 may be formed as a silicon nitride (SiCN) or silicon oxide (SiOx)-based inorganic film, but the present specification is not limited thereto.

A semiconductor insulating film SINS2 may be located on the first semiconductor insulating film SINS1. The second semiconductor insulating film SINS2 may be formed as a silicon oxide (SiOx)-based inorganic film, but the present specification is not limited thereto.

A plurality of contact terminals CTE may be located on the second semiconductor insulating film SINS2. Each of the plurality of contact terminals CTE may be connected to any one of the gate electrode GE, the source area SA, or the drain area DA of each of the plurality of pixel transistors PTR through a hole penetrating through the first semiconductor insulating film SINS1 and the second semiconductor insulating film SINS2. The plurality of contact terminals CTE may be formed of any one of copper (Cu), aluminum (AI), tungsten (W), molybdenum (Mo), chromium (Cr), gold (Au), titanium (Ti), nickel (Ni), or neodymium (Nd), or an alloy including any one thereof.

A third semiconductor insulating film SINS3 may be located on a side surface of each of the plurality of contact terminals CTE. An upper surface of each of the plurality of contact terminals CTE may be exposed without being covered by the third semiconductor insulating film SINS3. The third semiconductor insulating film SINS3 may be formed as a silicon oxide (SiOx)-based inorganic film, but the present specification is not limited thereto.

The light-emitting element backplane EBP includes first to eighth metal layers ML1 to ML8, reflective metal layers RL1 to RL4, a plurality of vias VA1 to VA10, and a step layer STPL. In addition, the light-emitting element backplane EBP includes a plurality of interlayer insulating films INS1 to INS10 located between/amongst the first to eighth metal layers ML1 to ML8.

The first to eighth metal layers ML1 to ML8 serve to implement a circuit of a sub-pixel SP by connecting the plurality of contact terminals CTE exposed from the semiconductor backplane SBP.

A first interlayer insulating film INS1 may be located on the semiconductor backplane SBP. Each of the first vias VA1 may penetrate through the first interlayer insulating film INS1, and may be connected to the contact terminal CTE exposed from the semiconductor backplane SBP. Each of the first metal layers ML1 may be located on the first interlayer insulating film INS1, and may be connected to the first via VA1.

A second interlayer insulating film INS2 may be located on the first interlayer insulating film INS1 and the first metal layers ML1. Each of the second vias VA2 may be connected to the first metal layer ML1 exposed by penetrating through the second interlayer insulating film INS2. Each of the second metal layers ML2 may be located on the second interlayer insulating film INS2 and may be connected to the second via VA2.

A third interlayer insulating film INS3 may be located on the second interlayer insulating film INS2 and the second metal layers ML2. Each of the third vias VA3 may be connected to the second metal layer ML2 exposed by penetrating through the third interlayer insulating film INS3. Each of the third metal layers ML3 may be located on the third interlayer insulating film INS3 and may be connected to the third via VA3.

A fourth interlayer insulating film INS4 may be located on the third interlayer insulating film INS3 and the third metal layers ML3. Each of the fourth vias VA4 may be connected to the third metal layer ML3 exposed by penetrating through the fourth interlayer insulating film INS4. Each of the fourth metal layers ML4 may be located on the fourth interlayer insulating film INS4 and may be connected to the fourth via VA4.

A fifth interlayer insulating film INS5 may be located on the fourth interlayer insulating film INS4 and the fourth metal layers ML4. Each of the fifth vias VA5 may be connected to the fourth metal layer ML4 exposed by penetrating through the fifth interlayer insulating film INS5. Each of the fifth metal layers ML5 may be located on the fifth interlayer insulating film INS5 and may be connected to the fifth via VA5.

A sixth interlayer insulating film INS6 may be located on the fifth interlayer insulating film INS5 and the fifth metal layers ML5. Each of the sixth vias VA6 may be connected to the fifth metal layer ML5 exposed by penetrating through the sixth interlayer insulating film INS6. Each of the sixth metal layers ML6 may be located on the sixth interlayer insulating film INS6 and may be connected to the sixth via VA6.

A seventh interlayer insulating film INS7 may be located on the sixth interlayer insulating film INS6 and the sixth metal layers ML6. Each of the seventh vias VA7 may be connected to the sixth metal layer ML6 exposed by penetrating through the seventh interlayer insulating film INS7. Each of the seventh metal layers ML7 may be located on the seventh interlayer insulating film INS7 and may be connected to the seventh via VA7.

An eighth interlayer insulating film INS8 may be located on the seventh interlayer insulating film INS7 and the seventh metal layers ML7. Each of the eighth vias VA8 may be connected to the seventh metal layer ML7 exposed by penetrating through the eighth interlayer insulating film INS8. Each of the eighth metal layers ML8 may be located on the eighth interlayer insulating film INS8 and may be connected to the eighth via VA8.

The first to eighth metal layers ML1 to ML8 and the first to eighth vias VA1 to VA8 may be formed of substantially the same material. The first to eighth metal layers ML1 to ML8 and the first to eighth vias VA1 to VA8 may be formed of any one of copper (Cu), aluminum (AI), tungsten (W), molybdenum (Mo), chromium (Cr), gold (Au), titanium (Ti), nickel (Ni), or neodymium (Nd), or an alloy including any one thereof. The first to eighth vias VA1 to VA8 may be formed of substantially the same material. The first to eighth interlayer insulating films INS1 to INS8 may be formed as a silicon oxide (SiOx)-based inorganic film, but the present specification is not limited thereto.

A thickness of the first metal layer ML1, a thickness of the second metal layer ML2, a thickness of the third metal layer ML3, a thickness of the fourth metal layer ML4, a thickness of the fifth metal layer ML5, and a thickness of the sixth metal layer ML6 may be greater than a thickness of the first via VA1, a thickness of the second via VA2, a thickness of the third via VA3, a thickness of the fourth via VA4, a thickness of the fifth via VA5, and a thickness of the sixth via VA6, respectively. Each of the thickness of the second metal layer ML2, the thickness of the third metal layer ML3, the thickness of the fourth metal layer ML4, the thickness of the fifth metal layer ML5, and the thickness of the sixth metal layer ML6 may be greater than the thickness of the first metal layer ML1. The thickness of the second metal layer ML2, the thickness of the third metal layer ML3, the thickness of the fourth metal layer ML4, the thickness of the fifth metal layer ML5, and the thickness of the sixth metal layer ML6 may be substantially the same.

Each of a thickness of the seventh metal layer ML7 and a thickness of the eighth metal layer ML8 may be greater than each of the thickness of the first metal layer ML1, the thickness of the second metal layer ML2, the thickness of the third metal layer ML3, the thickness of the fourth metal layer ML4, the thickness of the fifth metal layer ML5, and the thickness of the sixth metal layer ML6. Each of the thickness of the seventh metal layer ML7 and the thickness of the eighth metal layer ML8 may be greater than each of a thickness of the seventh via VA7 and a thickness of the eighth via VA8. Each of the thickness of the seventh via VA7 and the thickness of the eighth via VA8 may be greater than each of the thickness of the first via VA1, the thickness of the second via VA2, the thickness of the third via VA3, the thickness of the fourth via VA4, the thickness of the fifth via VA5, and the thickness of the sixth via VA6. The thickness of the seventh metal layer ML7 and the thickness of the eighth metal layer ML8 may be substantially the same.

A ninth interlayer insulating film INS9 may be located on the eighth interlayer insulating film INS8 and the eighth metal layers ML8. The ninth interlayer insulating film INS9 may be formed as a silicon oxide (SiOx)-based inorganic film, but the present specification is not limited thereto.

Each of the ninth vias VA9 may be connected to the eighth metal layer ML8 exposed by penetrating through the ninth interlayer insulating film INS9. The ninth vias VA9 may be formed of any one of copper (Cu), aluminum (AI), tungsten (W), molybdenum (Mo), chromium (Cr), gold (Au), titanium (Ti), nickel (Ni), or neodymium (Nd), or an alloy including any one thereof.

Each of first reflective electrodes RL1 may be located on the ninth interlayer insulating film INS9 and may be connected to the ninth via VA9. The first reflective electrodes RL1 may be formed of any one of copper (Cu), aluminum (AI), tungsten (W), molybdenum (Mo), chromium (Cr), gold (Au), titanium (Ti), nickel (Ni), or neodymium (Nd), or an alloy including any one thereof.

Each of second reflective electrodes RL2 may be located on the first reflective electrode RL1. The second reflective electrodes RL2 may be formed of any one of copper (Cu), aluminum (AI), tungsten (W), molybdenum (Mo), chromium (Cr), gold (Au), titanium (Ti), nickel (Ni), or neodymium (Nd), or an alloy including any one thereof. For example, the second reflective electrodes RL2 may be formed of titanium nitride (TiN).

In a portion overlapping the first sub-pixel SP1, a step layer STPL may be located on the second reflective electrode RL2. The step layer STPL may not be located in a portion overlapping the second sub-pixel SP2 and the third sub-pixel SP3. The step layer STPL may be formed of a silicon carbon nitride (SiCN) or silicon oxide (SiOx)-based inorganic film, but the embodiments of the present specification are not limited thereto.

In portion overlapping the first sub-pixel SP1, a third reflective electrode RL3 may be located on the second reflective electrode RL2 and the step layer STPL. In portion overlapping the second and third sub-pixels SP2 and SP3, the third reflective electrode RL3 may be located on the second reflective electrode RL2. The third reflective electrodes RL3 may be formed of any one of copper (Cu), aluminum (AI), tungsten (W), molybdenum (Mo), chromium (Cr), gold (Au), titanium (Ti), nickel (Ni), or neodymium (Nd), or an alloy including any one thereof. At least one of the first reflective electrode RL1, the second reflective electrode RL2, and the third reflective electrode RL3 may be omitted.

Each of fourth reflective electrodes RL4 may be located on the third reflective electrode RL3. The fourth reflective electrode RL4 may include a metal having a high reflectance to be advantageous in reflecting light. The fourth reflective electrode RL4 may be formed of aluminum (AI), a stacked structure (Ti/Al/Ti) of aluminum and titanium, a stacked structure (ITO/AI/ITO) of aluminum and ITO, an APC alloy, which is an alloy of silver (Ag), palladium (Pd), or copper (Cu), or a stacked structure (ITO/APC/ITO) of an APC alloy and ITO, but the present specification is not limited thereto.

A tenth interlayer insulating film INS10 may be located on the ninth interlayer insulating film INS9 and the fourth reflective electrode RL4. The tenth interlayer insulating film INS10 may be formed as a silicon oxide (SiOx)-based inorganic film, but the present specification is not limited thereto.

Each of the tenth vias VA10 may be connected to the ninth metal layer ML9 exposed by penetrating through the tenth interlayer insulating film INS10. The tenth vias VA10 may be formed of any one of copper (Cu), aluminum (AI), tungsten (W), molybdenum (Mo), chromium (Cr), gold (Au), titanium (Ti), nickel (Ni), or neodymium (Nd), or an alloy including any one thereof. Due to the step layer STPL, a thickness of the tenth via VA10 in the first sub-pixel SP1 may be less than a thickness of the tenth via VA10 in each of the second and third sub-pixels SP2 and SP3.

The light-emitting element layer EML may be located on the light-emitting element backplane EBP. The light-emitting element layer EML may include light-emitting elements LE each including a first electrode AND, a light-emitting layer IL, and a second electrode CAT, and a pixel-defining layer PDL.

The first electrode AND may be located on the tenth interlayer insulating film INS10 and may be connected to the tenth via VA10. The first electrode AND may be connected to the drain area DA or the source area SA of the pixel transistor PTR through the tenth via VA10, the first to fourth reflective electrodes RL1 to RL4, the first to ninth vias VA1 to VA9, the first to eighth metal layers ML1 to ML8, and the contact terminal CTE. The first electrode AND may be formed of any one of copper (Cu), aluminum (AI), tungsten (W), molybdenum (Mo), chromium (Cr), gold (Au), titanium (Ti), nickel (Ni), or neodymium (Nd), or an alloy including any one thereof. For example, the first electrode AND may be formed of titanium nitride (TiN).

The pixel-defining layer PDL may be located on a partial area of the first electrode AND. The pixel-defining layer PDL may cover an edge of the first electrode AND. The pixel-defining layer PDL serves to partition the first light-emitting areas EA1, the second light-emitting areas EA2, and the third light-emitting areas EA3.

The first light-emitting area EA1 may be defined as an area in which the first electrode AND, the first light-emitting layer IL1, and the second electrode CAT are sequentially stacked in the first sub-pixel SP1 to emit light. The second light-emitting area EA2 may be defined as an area in which the first electrode AND, the second light-emitting layer IL2, and the second electrode CAT are sequentially stacked in the second sub-pixel SP2 to emit light. The third light-emitting area EA3 may be defined as an area in which the first electrode AND, the third light-emitting layer IL3, and the second electrode CAT are sequentially stacked in the third sub-pixel SP3 to emit light.

The pixel-defining layer PDL may include first to third pixel-defining layers PDL1, PDL2, and PDL3. The first pixel-defining layer PDL1 may be located on the edge of the first electrode AND, the second pixel-defining layer PDL2 may be located on the first pixel-defining layer PDL1, and the third pixel-defining layer PDL3 may be located on the second pixel-defining layer PDL2. The first pixel-defining layer PDL1, the second pixel-defining layer PDL2, and the third pixel-defining layer PDL3 may be formed as a silicon oxide (SiOx)-based inorganic film, but the present specification is not limited thereto.

The light-emitting layer IL may include a first light-emitting layer IL1, a second light-emitting layer IL2, and a third light-emitting layer IL3. The first light-emitting layer IL1, the second light-emitting layer IL2, and the third light-emitting layer IL3 may emit light of different colors. As an example, the first light-emitting layer IL1 may emit red light, the second light-emitting layer IL2 may emit green light, and the third light-emitting layer IL3 may emit blue light, but the present disclosure is not limited thereto.

The first to third light-emitting layers IL1, IL2, and IL3 located adjacent to each other in the first direction (X-axis direction) may be separated by the pixel-defining layer PDL. The display panel 410 according to one or more embodiments may reduce or prevent leakage current between the sub-pixels SP1, SP2, and SP3 located adjacent to each other and reduce or prevent a color interference phenomenon by disconnecting the first to third light-emitting layers IL1, IL2, and IL3 located adjacent to each other.

The second electrode CAT may be located on the light-emitting layer IL. The second electrode CAT may be a common electrode. The second electrode CAT may be formed of a transparent conductive material (TCO), such as ITO or IZO capable of transmitting light, or a semi-transmissive conductive material, such as magnesium (Mg), silver (Ag), or an alloy of magnesium (Mg) and silver (Ag). When the second electrode CAT is formed of a semi-transmissive conductive material, light emission efficiency may be increased in each of the first to third sub-pixels SP1, SP2, and SP3 by micro cavities.

The encapsulation layer TFE may be located on the light-emitting element layer EML. The encapsulation layer TFE may include at least one inorganic film to reduce or prevent permeation of oxygen or moisture into the light-emitting element layer EML. In addition, the encapsulation layer TFE may include at least one organic film to protect the light-emitting element layer EML from foreign substances, such as dust. For example, the encapsulation layer TFE may include a first encapsulation layer TFE1, a second encapsulation layer TFE2, and a third encapsulation layer TFE3.

The first encapsulation layer TFE1 may be located on the second electrode CAT, the second encapsulation layer TFE2 may be located on the first encapsulation layer TFE1, and the third encapsulation layer TFE3 may be located on the second encapsulation layer TFE2. The first encapsulation layer TFE1 and the third encapsulation layer TFE3 may be formed as a multi-film in which one or more inorganic films of a silicon nitride layer (SiNx), a silicon oxynitride layer (SiON), a silicon oxide layer (SiOx), a titanium oxide layer (TiOx), or an aluminum oxide layer (AIOx) are alternately stacked. The second encapsulation layer TFE2 may be a monomer.

Alternatively, the second encapsulation layer TFE2 may be an organic film made of an acrylic resin, an epoxy resin, a phenolic resin, a polyamide resin, or a polyimide resin.

An adhesive layer ADL may be a layer for adhering the encapsulation layer TFE and the optical layer OPL. The adhesive layer ADL may be a double-sided adhesive member. In addition, the adhesive layer ADL may be a transparent adhesive member, such as a transparent adhesive or a transparent adhesive resin.

The optical layer OPL may include a plurality of lenses LNS and a filling layer FIL. Each of the plurality of lenses LNS may be a structure for increasing a ratio of light directed to the front of the display device 10. Each of the plurality of lenses LNS may have a cross-sectional shape that is convex in an upward direction.

The filling layer FIL may be located on the plurality of lenses LNS. The filling layer FIL may have a refractive index (e.g., predetermined refractive index) so that light travels in the third direction (Z-axis direction) at an interface between the plurality of lenses LNS and the filling layer FIL. In addition, the filling layer FIL may be a planarization layer. The filling layer FIL may be an organic film made of an acryl resin, an epoxy resin, a phenolic resin, a polyamide resin, or a polyimide resin.

The cover layer CVL may be located on the filling layer FIL. The cover layer CVL may be a glass substrate or a polymer resin, such as resin. When the cover layer CVL is a glass substrate, the cover layer CVL may be attached onto the filling layer FIL. In this case, the filling layer FIL may serve to adhere the cover layer CVL. When the cover layer CVL is a glass substrate, the cover layer CVL may serve as an encapsulation substrate. When the cover layer CVL is a polymer resin, such as resin, the cover layer CVL may be directly applied on the filling layer FIL.

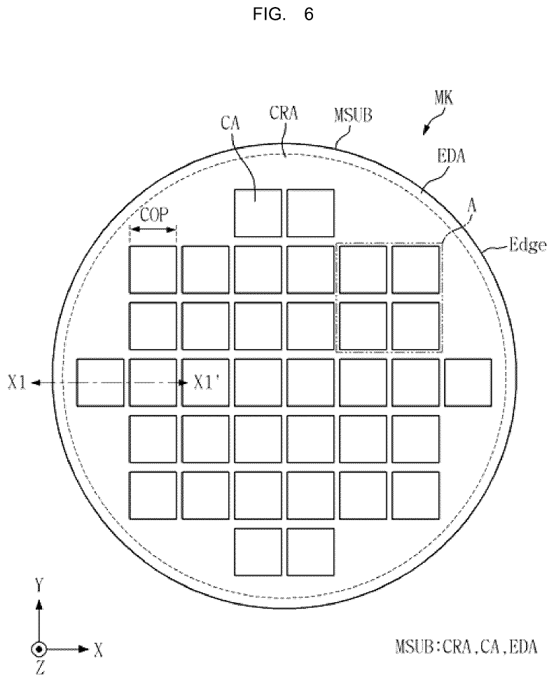

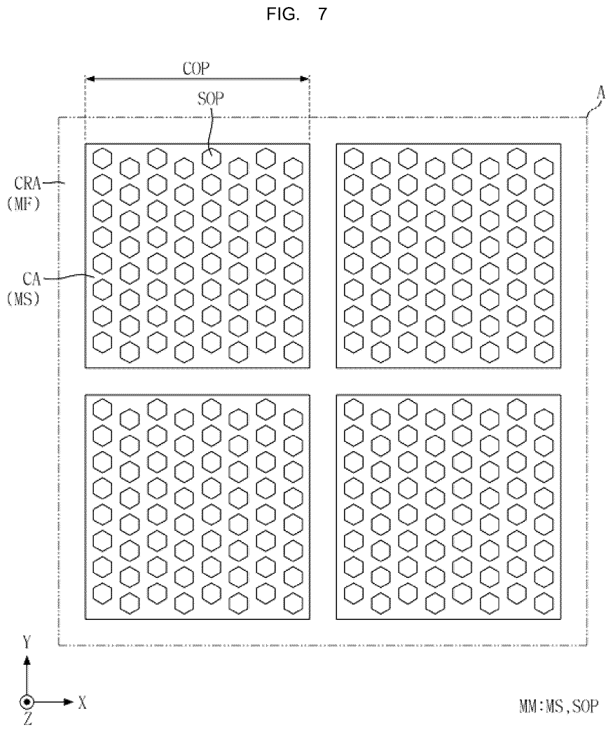

FIG. 6 is a schematic plan view of a mask MK according to one or more embodiments. FIG. 7 is an enlarged plan view of area A of FIG. 6. The mask according to one or more embodiments illustrated in FIG. 6 may be used in a process of depositing at least a portion of the light-emitting layer IL of the display panel 410 described with reference to FIG. 5.

Referring to FIGS. 6 and 7, the mask MK according to one or more embodiments may be a mask used to manufacture an ultra-high resolution display. As an example, the mask MK may be a mask used to manufacture a display included in an extended reality device (XR device), such as a VR device, AR device, or mixed reality (“MR”) device.

The mask MK according to one or more embodiments may be used to perform a deposition process of the sub-pixels (SP1, SP2, and SP3 in FIG. 5) on a silicon wafer rather than a large-area substrate used in the conventional display. In the case of the display included in the extended reality device, because a screen thereof is positioned directly in front of the user's eyes, the display may have a small screen rather than a large-area screen. In addition, because the display is positioned close to the user's eyes, ultra-high resolution may be suitable. For example, the display included in the extended reality device may suitably use resolution of approximately 1000 PPI or more, and may suitably use ultra-high resolution of about 2000 PPI or more. Therefore, the mask MK according to one or more embodiments may be a mask used to manufacture such an ultra-high resolution display. The mask MK according to one or more embodiments may include all of the masks MK1, MK2, MK3, and MK5 described later.

The mask MK according to one or more embodiments may include a mask substrate MSUB.

The mask substrate MSUB according to one or more embodiments may include a silicon wafer. Because the silicon wafer may be processed more finely and precisely than the large-area substrate by utilizing technologies developed in the semiconductor process, the silicon wafer may be employed as a substrate of the ultra-high resolution display. The mask MK according to one or more embodiments may use the same silicon wafer to form pixels on the silicon wafer of such an ultra-high resolution display.

The mask substrate MSUB according to one or more embodiments may have a shape corresponding to the silicon wafer of the ultra-high resolution display. For example, the mask substrate MSUB may have the same size or shape as the silicon wafer of the ultra-high resolution display. However, the mask substrate MSUB is not limited thereto, and may also include a large-area substrate. For example, the mask substrate MSUB may also include materials, such as glass, quartz, and polymer resin.

The mask substrate MSUB according to one or more embodiments may include a plurality of cell areas CA, a cell peripheral area CRA, and an edge area EDA.

The cell peripheral area CRA according to one or more embodiments may surround the plurality of cell areas CA. The cell peripheral area CRA may be an area where a mask frame MF overlaps. In plan view, the mask frame MF may define a mask opening COP, and in plan view, the mask frame MF may surround the mask opening COP. The mask frame MF may be an area that supports the mask MK. The structure of the mask frame MF will be described later.

According to one or more embodiments, a plurality of cell areas CA may be formed, and each cell area CA may be spaced apart. The cell area CA may be a portion overlapping the mask opening COP.

The cell area CA according to one or more embodiments may be an area where a mask membrane MM overlaps. The mask membrane MM may include a pixel opening SOP and a mask shadow MS. In plan view, the mask shadow MS may be integrally formed to entirely surround the pixel opening SOP. In addition, in plan view, the mask frame MF may be integrally formed to entirely surround the mask shadow MS.

In other words, in plan view, the mask shadow MS may be in the form of a pattern that exposes the pixel opening SOP and that is integrally formed, and in plan view, the mask frame MF may be the form of a pattern that exposes the mask opening COP and that is integrally formed.

The edge area EDA according to one or more embodiments may be an edge of the mask substrate MSUB and an area surrounding the edge. In other words, the edge area EDA may refer to an outer portion of the mask substrate MSUB.

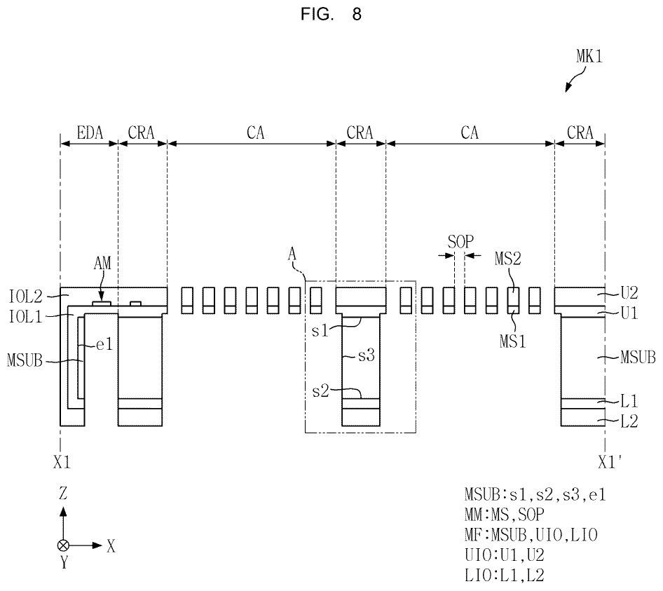

FIG. 8 is a cross-sectional view taken along the line X1-X1′ of FIG. 6.

Referring to FIG. 8, the mask frame MF according to one or more embodiments may be positioned in a portion overlapping the cell peripheral area CRA. The mask frame MF may include a mask substrate MSUB, an upper inorganic layer UIO, and a lower inorganic layer LIO. The upper inorganic layer UIO may be positioned on an upper surface s1 of the mask substrate MSUB, and the lower inorganic layer LIO may be positioned on a lower surface s2 of the mask substrate MSUB. The upper inorganic layer UIO may include a first upper inorganic layer U1 and a second upper inorganic layer U2, and the lower inorganic layer LIO may include a first lower inorganic layer L1 and a second lower inorganic layer L2. Because the mask substrate MSUB has already been mentioned, the description thereof will be omitted.

The first upper inorganic layer U1 according to one or more embodiments may be positioned on the upper surface s1 of the mask substrate MSUB, and may be in contact with the upper surface s1. The first upper inorganic layer U1 may include the same material as a first mask shadow MS1 of the mask shadow MS described later. In a process of manufacturing the mask MK1, the first mask shadow MS1 and the first upper inorganic layer U1 may be integrally formed, and then may be formed into the illustrated shapes through a subsequent etching process. In addition, the first upper inorganic layer U1 may include the same material as a first mask inorganic layer IOL1 positioned in a portion overlapping the edge area EDA. That is, in the process of manufacturing the mask MK1, the first mask shadow MS1, the first mask inorganic layer IOL1, and the first upper inorganic layer U1 may be integrally formed, and then may be formed into the illustrated shapes through a subsequent etching process. Depending on the embodiment, the term referring to the first mask inorganic layer IOL1 may be used interchangeably with the first upper inorganic layer U1. The manufacturing process will be described later.

The first upper inorganic layer U1 according to one or more embodiments may include an inorganic insulating material. As an example, the first upper inorganic layer U1 may be silicon oxide, but is not limited thereto.

The second upper inorganic layer U2 according to one or more embodiments may be positioned on the first upper inorganic layer U1, and may be in contact with the first upper inorganic layer U1. The second upper inorganic layer U2 may include the same material as a second mask shadow MS2 of the mask shadow MS described later. In a process of manufacturing the mask MK1, the second mask shadow MS2 and the second upper inorganic layer U2 may be integrally formed, and then may be formed into the illustrated shapes through an etching process. In addition, the second upper inorganic layer U2 may include the same material as a second mask inorganic layer IOL2 positioned in a portion overlapping the edge area EDA. In the process of manufacturing the mask MK1, the second mask shadow MS2, the second mask inorganic layer IOL2, and the second upper inorganic layer U2 may be integrally formed, and then may be formed into the illustrated shapes through a subsequent etching process. Depending on the embodiment, the term referring to the second mask inorganic layer IOL2 may be used interchangeably with the second upper inorganic layer U2. The manufacturing process will be described later.

The second upper inorganic layer U2 according to one or more embodiments may include an inorganic insulating material. As an example, the second upper inorganic layer U2 may be silicon nitride, but is not limited thereto.

The first upper inorganic layer U1 and the second upper inorganic layer U2 may have different stress properties. The mask MK1 may reduce or minimize the stress properties included in the upper inorganic layer UIO by stacking the first upper inorganic layer U1 and the second upper inorganic layer U2 having different stress properties. As an example, when the first upper inorganic layer U1 is formed of an inorganic insulating material including compressive stress, the stacked structure may be designed such that the second upper inorganic layer U2 is formed of an inorganic insulating material having tensile stress.

The first lower inorganic layer L1 according to one or more embodiments may be positioned on the lower surface s2 of the mask substrate MSUB, and may be in contact with the lower surface s2. The first lower inorganic layer L1 may include the same material as the first upper inorganic layer U1. In a process of manufacturing the mask MK1, the first upper inorganic layer U1 and the first lower inorganic layer L1 may be integrally formed, and then may be formed into the illustrated shapes through an etching process. In addition, the first lower inorganic layer L1 may include the same material as the first mask inorganic layer IOL1 positioned in the portion overlapping the edge area EDA. That is, in the process of manufacturing the mask MK1, the first mask shadow MS1, the first mask inorganic layer IOL1, the first upper inorganic layer U1, and the first lower inorganic layer L1 may be integrally formed, and then may be formed into the illustrated shapes through a subsequent etching process. Depending on the embodiment, the term referring to the first mask inorganic layer IOL1 may be used interchangeably with the first lower inorganic layer L1. The manufacturing process will be described later.

The first lower inorganic layer L1 according to one or more embodiments may include an inorganic insulating material. As an example, the first lower inorganic layer L1 may be silicon oxide, but is not limited thereto.

The second lower inorganic layer L2 according to one or more embodiments may be positioned on the first lower inorganic layer L1, and may be in contact with the first lower inorganic layer L1. The second lower inorganic layer L2 may include the same material as the second upper inorganic layer U2. In a process of manufacturing the mask MK1, the second upper inorganic layer U2 and the second lower inorganic layer L2 may be integrally formed, and then may be formed into the illustrated shapes through an etching process. In addition, the second lower inorganic layer L2 may include the same material as the second mask inorganic layer IOL2 positioned in the portion overlapping the edge area EDA. That is, in the process of manufacturing the mask MK1, the second mask shadow MS2, the second mask inorganic layer IOL2, the second upper inorganic layer U2, and the second lower inorganic layer L2 may be integrally formed, and then may be formed into the illustrated shapes through a subsequent etching process. Depending on the embodiment, the term referring to the second mask inorganic layer IOL2 may be used interchangeably with the second lower inorganic layer L2. The manufacturing process will be described later.

The second lower inorganic layer L2 according to one or more embodiments may include an inorganic insulating material. As an example, the second lower inorganic layer L2 may be silicon nitride, but is not limited thereto.

The first lower inorganic layer L1 and the second lower inorganic layer L2 according to one or more embodiments may have different stress properties, similar to the first upper inorganic layer U1 and the second upper inorganic layer U2. The redundant descriptions thereof will be omitted.

In some embodiments, the mask substrate MSUB position in the portion overlapping the edge area EDA may include an edge surface e1. The edge surface e1 may refer to an edge of the mask substrate MSUB positioned in the portion overlapping the edge area EDA.

The upper surface s1, the lower surface s2, and the edge surface e1 of the mask substrate MSUB positioned in the portion overlapping the edge area EDA may be entirely covered with the first mask inorganic layer IOL1, and may be in contact with the first mask inorganic layer IOL1. In addition, the upper surface s1, the lower surface s2, and the edge surface e1 of the mask substrate MSUB positioned in the portion overlapping the edge area EDA may be entirely covered with the second mask inorganic layer IOL2.

In other words, it may be described that the edge surface e1 of the mask substrate MSUB positioned in the portion overlapping the edge area EDA may be entirely covered with the first upper inorganic layer U1 or the first lower inorganic layer L1, and may be in contact with the first upper inorganic layer U1 or the first lower inorganic layer L1. In addition, it may be described that the edge surface e1 of the mask substrate MSUB positioned in the portion overlapping the edge area EDA may be entirely covered with the second upper inorganic layer U2 or the second lower inorganic layer L2.

An alignment mark AM according to one or more embodiments may be positioned on the first mask inorganic layer IOL1 in a portion overlapping the edge area EDA and a peripheral portion of the edge area EDA. The alignment mark AM may align the display panel 410 illustrated in FIG. 5 with the mask MK1 according to one or more embodiments. The shape of the alignment mark AM illustrated in the drawing is not limited thereto, and the alignment mark AM may have various shapes and arrangements.

The mask opening COP according to one or more embodiments may be defined by a plurality of mask frames MF located adjacent to each other. The mask frames MF may surround the mask opening COP. The cell area CA may be defined by the mask opening COP.

The mask membrane MM according to one or more embodiments may be positioned in a portion overlapping the cell area CA. The mask membrane MM may include a plurality of mask shadows MS and pixel openings SOP. The pixel opening SOP may be positioned between the plurality of mask shadows MS adjacent to each other.

The pixel opening SOP according to one or more embodiments may be named “hole” or “mask hole.” The plurality of pixel openings SOP may penetrate through the mask frame MF along a thickness direction (e.g., third direction (Z-axis direction)) of the mask MK1. The plurality of pixel openings SOP may be formed by etching portions of the mask substrate MSUB, the first mask inorganic layer IOL1, and the second mask inorganic layer IOL2 from a direction of the lower surface s2 of the mask substrate MSUB during the manufacturing process. The manufacturing process will be described later.

When a deposition material is evaporated from a deposition source inside a deposition device, the plurality of mask shadows MS may serve as blocking portions that mask a substrate to be deposited (e.g., the display panel 410 or the backplane substrate). Accordingly, the deposition material generated from the deposition source may be deposited on a surface of the substrate (e.g., the display panel 410 or the backplane substrate) through the pixel opening SOP of the mask membrane MM.

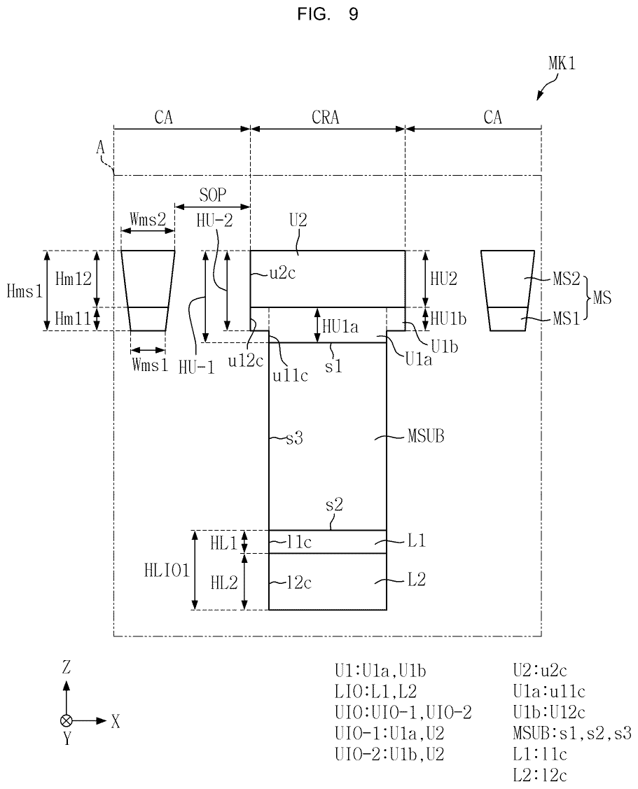

FIG. 9 is an enlarged cross-sectional view of area A of FIG. 8.

Referring to FIG. 9, the mask shadow MS according to one or more embodiments may include a first mask shadow MS1 and a second mask shadow MS2, and the first mask shadow MS1 and the second mask shadow MS2 may be sequentially stacked in the third direction (Z-axis direction).

The mask shadow MS may have a reverse tapered shape. In the process of manufacturing the mask MK1, a portion of the lower surface and side surface of the first mask shadow MS1 of the mask shadow MS may be etched by an etching process performed in the direction of the lower surface s2 of the mask substrate MSUB. As a result, a width Wms1 of the lower surface of the first mask shadow MS1 in the first direction (X-axis direction) may be less than a width Wms2 of the upper surface of the second mask shadow MS2 in the first direction (X-axis direction). However, the form of the mask shadow MS is not limited thereto.

In some embodiments, a height Hm11 of the first mask shadow MS1 in the third direction (Z-axis direction) may be less than a height Hm12 of the second mask shadow MS2 in the third direction (Z-axis direction). However, this is only an example, and the present disclosure is not limited thereto.

A height HU2 of the second upper inorganic layer U2 according to one or more embodiments may be the same as the height Hm12 of the second mask shadow MS2 included in the mask shadow MS. Corresponding redundant descriptions will be omitted.

The first upper inorganic layer U1 according to one or more embodiments may include a first portion U1a and a second portion U1b having different heights. The first portion Ula may be positioned at a central portion of the first upper inorganic layer U1, and may occupy most of the area of the first upper inorganic layer U1. In addition, the second portion U1b may be positioned at the edge of the first upper inorganic layer U1, and may be a portion facing the cell area CA.

The first upper inorganic layer U1 of the mask MK1 may be partially etched by an etching process performed in the direction of the lower surface s2 of the mask substrate MSUB. As a result, the first upper inorganic layer U1 may include the first portion Ula and the second portion U1b having different heights.

In some embodiments, a height HU1a of the first portion Ula of the first upper inorganic layer U1 may be greater than a height HU1b of the second portion U1b of the first upper inorganic layer U1. In addition, the height HU1a of the first portion U1a of the first upper inorganic layer U1 may be greater than the height Hm11 of the first mask shadow MS1.

In some embodiments, the height HU1b of the second portion U1b of the first upper inorganic layer U1 may be the same as the height Hm11 of the first mask shadow MS1. However, this is only an example, and the present disclosure is not limited thereto.

In some embodiments, the height HU1a of the first portion Ula of the first upper inorganic layer U1 may be less than the height of the second upper inorganic layer U2. However, this is only an example, and the present disclosure is not limited thereto.

The upper inorganic layer UIO according to one or more embodiments may have a first upper surface portion UIO-1 and a second upper surface portion UIO-2. The first upper surface portion UIO-1 may be a portion including the first portion Ula of the first upper inorganic layer U1 and the second upper inorganic layer U2, and the second upper surface portion UIO-2 may be a portion including the second portion U1b of the first upper inorganic layer U1 and the second upper inorganic layer U2. A height HU-1 of the first upper surface portion UIO-1 may be greater than a height HU-2 of the second upper surface portion UIO-2.

The mask substrate MSUB according to one or more embodiments may include a side surface s3 in addition to the upper surface s1 and the lower surface s2. The side surface s3 of the mask substrate MSUB may be positioned in a direction toward the cell area CA. The side surface s3 of the mask substrate MSUB may be one surface connecting the upper surface s1 and the lower surface s2.

In some embodiments, the side surface s3 of the mask substrate MSUB may be more depressed in the first direction (X-axis direction) than a side surface u2c of the second upper inorganic layer U2. In other words, the side surface s3 of the mask substrate MSUB may be more depressed in the first direction (X-axis direction) than a side surface u12c of the second portion U1b of the first upper inorganic layer U1, and may be positioned on the same line as a side surface u11c of the first portion Ula of the first upper inorganic layer U1. This may be caused by an etching process performed in the direction of the lower surface s2 of the mask substrate MSUB during the process of manufacturing the mask MK1. Corresponding redundant descriptions will be omitted.

A side surface I1c of the first lower inorganic layer L1 according to one or more embodiments may be positioned on the same line as the side surface s3 of the mask substrate MSUB. In other words, the side surface I1c of the first lower inorganic layer L1 may be more depressed in the first direction (X-axis direction) than the side surface u2c of the second upper inorganic layer U2. In addition, a side surface I2c of the second lower inorganic layer L2 according to one or more embodiments may be positioned on the same line as the side surface s3 of the mask substrate MSUB. This may be caused by an etching process performed in the direction of the lower surface s2 of the mask substrate MSUB during the process of manufacturing the mask MK1. Corresponding redundant descriptions will be omitted.

In some embodiments, the height HL1 of the first lower inorganic layer L1 may be the same as the height HU1a of the first portion Ula of the first upper inorganic layer U1. In addition, the height HL2 of the second lower inorganic layer L2 may be the same as the height HU2 of the second upper inorganic layer U2. In addition, the height HL2 of the second lower inorganic layer L2 may be the same as the height Hm12 of the second mask shadow MS2.

In some embodiments, a height HLIO1 of the lower inorganic layer LIO included in the mask MK1 may be greater than the height Hms1 of the mask shadow MS. In addition, the height HLIO1 of the lower inorganic layer LIO included in the mask MK1 may be greater than the height HU-2 of the second upper surface portion UIO-2 of the upper inorganic layer UIO.

In the mask MK1 included in one or more embodiments, the height HLIO1 of the lower inorganic layer LIO positioned below the mask substrate MSUB may have a greater value than the height HU-2 of the second portion UIO-2 of the upper inorganic layer UIO positioned above the mask substrate MSUB and the height Hms1 of the mask shadow MS. As a result, the mask MK1 according to one or more embodiments may form stress of the inorganic layer positioned above the mask substrate MSUB similar to that of the inorganic layer positioned below the mask substrate MSUB. That is, the mask MK1 may solve the problem of damage to the mask MK1 due to stress imbalance between an inorganic film positioned above the mask MK1 and an inorganic film positioned below the mask MK1 by forming a height of the inorganic layer positioned below the mask MK1 to be greater than a height of the inorganic layer positioned above the mask MK1.

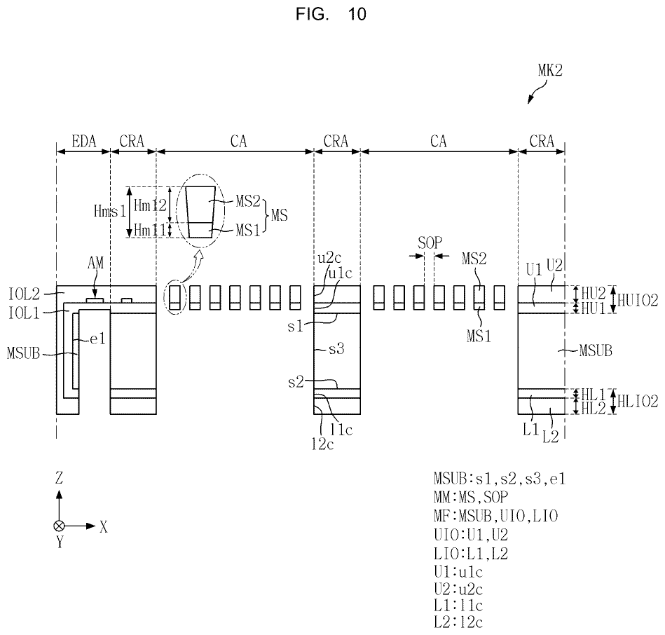

FIG. 10 is a cross-sectional view taken along the line X1-X1′ of FIG. 6, as still one or more other embodiments.

Referring to FIG. 10, a mask MK2 according to one or more embodiments may be different from the mask MK1 in that the side surface u1c of the first upper inorganic layer U1, the side surface s3 of the mask substrate MSUB, the side surface I1c of the first lower inorganic layer L1, and the side surface I2c of the second lower inorganic layer L2 may be positioned on the same line as the side surface u2c of the second upper inorganic layer U2. Hereinafter, a repeated description of the commonalities between the mask MK2 and the mask MK1 will not be repeated, and the differences therebetween will be described.

The first upper inorganic layer U1 included in the mask MK2 may have the same height HU1 as a whole. In addition, the side surface ulc of the first upper inorganic layer U1 facing the cell area CA may be positioned on the same line as the side surface u2c facing the cell area CA of the second upper inorganic layer U2.

In a process of manufacturing the mask MK2 according to one or more embodiments, the first upper inorganic layer U1 and the first mask shadow MS1 may be formed in the form currently illustrated by integrally forming the first upper inorganic layer U1 and the first mask shadow MS1, and by then performing an etching process of reducing an overall height of the first mask shadow MS1 as a subsequent process. Therefore, the height HU1 of the first upper inorganic layer U1 included in the mask MK2 may be greater than the height Hm11 of the first mask shadow MS1.

The side surface s3 of the mask substrate MSUB, the side surface I1c of the first lower inorganic layer L1, and the side surface I2c of the second lower inorganic layer L2 included in the mask MK2 may be positioned on the same line as the side surface u2c of the second upper inorganic layer U2 facing the cell area CA. Corresponding redundant descriptions will be omitted.

A height HUIO2 of the upper inorganic layer UIO included in the mask MK2 according to one or more embodiments may be same as a height HLIO2 of the lower inorganic layer LIO. However, the height Hms1 of the mask shadow MS included in the mask MK2 may be less than the height HLIO2 of the lower inorganic layer LIO.

In the mask MK2 included in one or more embodiments, the height HLIO2 of the lower inorganic layer LIO positioned below the mask substrate MSUB may have a greater value than the height Hms1 of the mask shadow MS positioned above the mask substrate MSUB. As a result, the mask MK2 may form stress of the inorganic layer positioned above the mask substrate MSUB similar to that of the inorganic layer positioned below the mask substrate MSUB. Therefore, the mask MK2 may solve damage to the mask caused by stress imbalance between the plurality of inorganic layers positioned above and below the mask substrate MSUB.

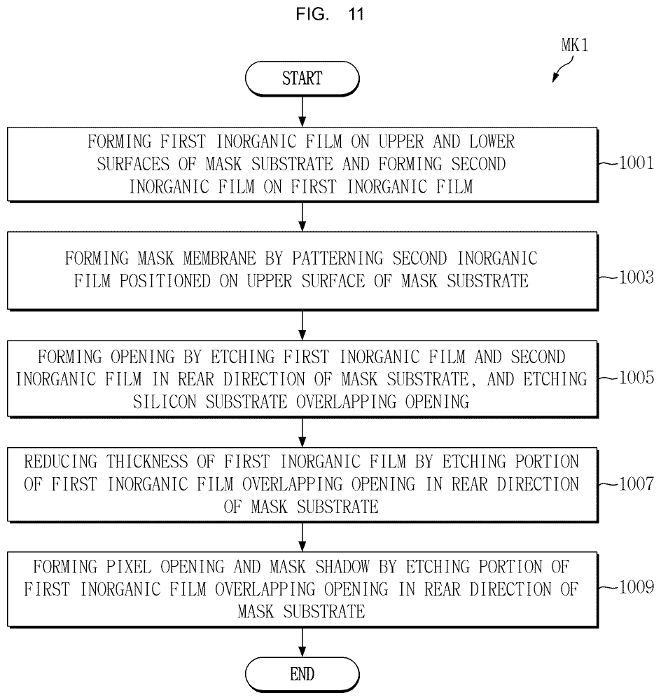

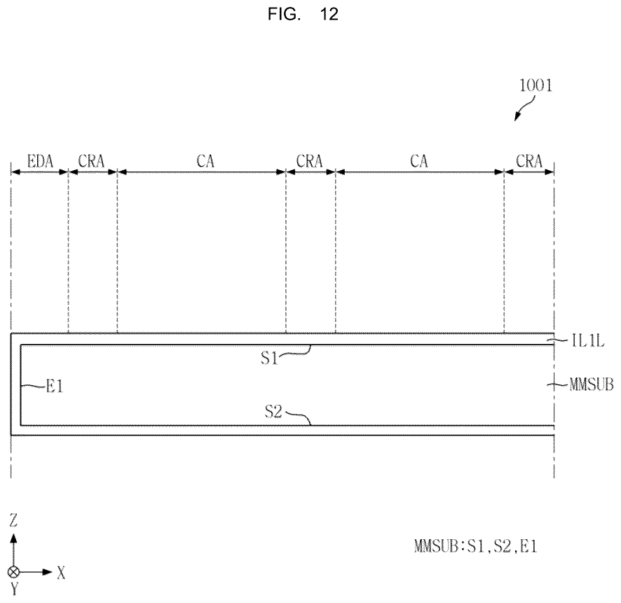

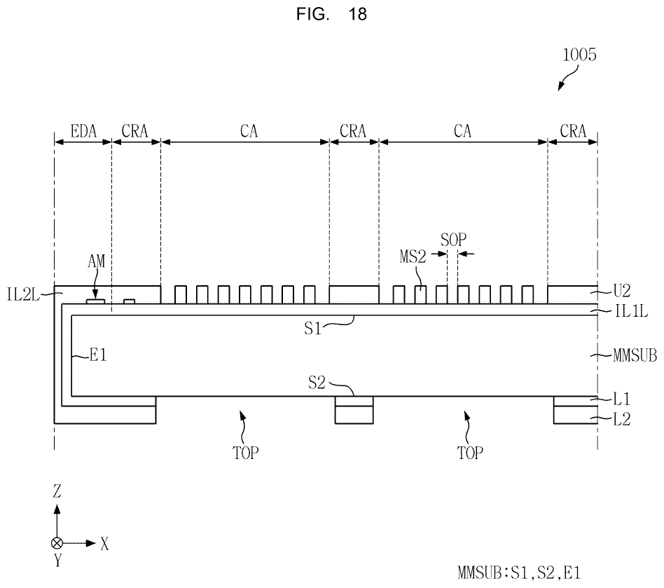

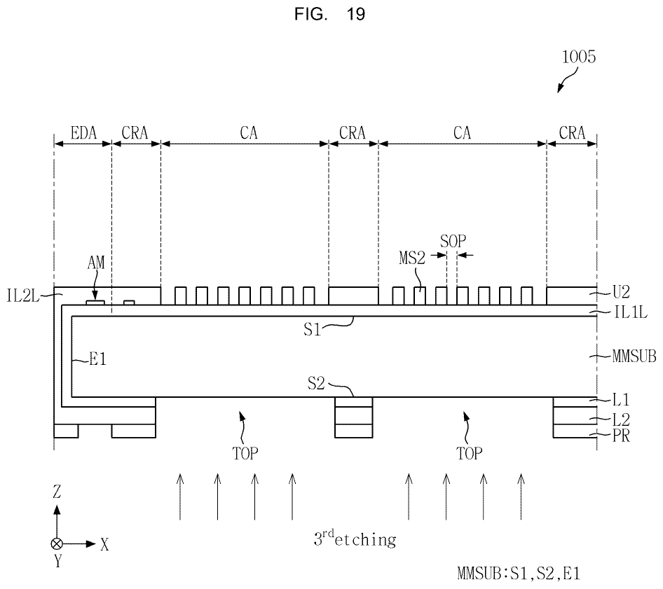

FIG. 11 is a flowchart describing a method for manufacturing the mask illustrated in FIG. 8. FIGS. 12 to 23 are process cross-sectional views for describing the method for manufacturing the mask of FIG. 8.

Hereinafter, a method for manufacturing the mask according to one or more embodiments will be described with reference to FIGS. 11 to 23. The following description is only a portion of the processes of manufacturing the mask, and processes for forming the components described with reference to the present document may be additionally performed before or after each operation. In addition, a process of manufacturing the mask known in the art may be additionally performed before or after each operation described below.

First, “an operation of forming a first inorganic film on the upper and lower surfaces of the mask substrate and forming a second inorganic film on the first inorganic film” will be described with reference to operation 1001 of FIG. 11.

Referring to FIG. 12, a mask mother substrate MMSUB including a plurality of cell areas CA, cell peripheral areas CRA, and edge areas EDA is prepared. The cell peripheral area CRA may refer to an area surrounding the plurality of cell areas CA, and the edge area EDA may refer to an edge area of the mask. The mask mother substrate MMSUB may include a silicon wafer.

Next, a first inorganic material layer IL1L is formed on an upper surface S1 and on a lower surface S2 of the mask mother substrate MMSUB. In the present process, the first inorganic material layer IL1L may be formed by inserting the mask mother substrate MMSUB into a slit. Therefore, the first inorganic material layer IL1L may be formed concurrently or substantially simultaneously on an edge surface E1 as well as on the upper and lower surfaces S1 and S2 of the mask mother substrate MMSUB. The first inorganic material layer IL1L may entirely cover the upper surface S1, the lower surface S2, and the edge surface E1 of the mask mother substrate MMSUB. The first inorganic material layer IL1L may include an inorganic insulating material. Corresponding redundant descriptions will be omitted.

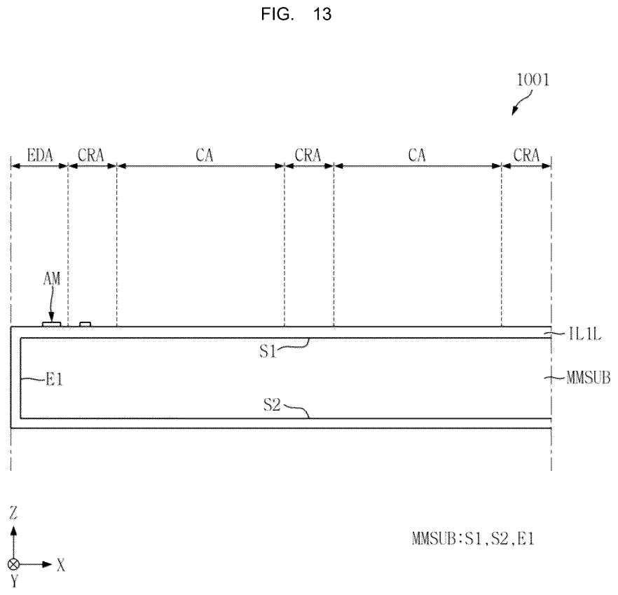

Next, referring to FIG. 13, an alignment mark AM may be formed on the first inorganic material layer IL1L in portions overlapping the edge area EDA, and overlapping the cell peripheral area CRA positioned adjacent to the edge area EDA. The alignment mark AM may be used to align the mask MK1 and the display panel 410 illustrated in FIG. 5. Depending on the embodiment, the present process may be omitted.

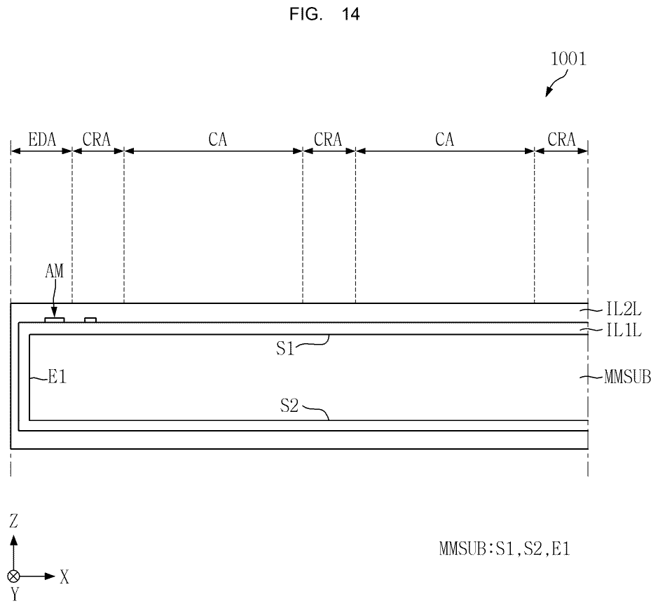

Next, referring to FIG. 14, a second inorganic material layer IL2L is formed on the first inorganic material layer IL1L. In the present process, similarly to the operation of forming the first inorganic material layer IL1L, the second inorganic material layer IL2L may be formed by inserting the mask mother substrate MMSUB into the slit. The second inorganic material layer IL2L may be concurrently or substantially simultaneously formed on the upper surface S1, the lower surface S2, and the edge surface E1 of the mask mother substrate MMSUB, and may entirely cover the upper surface S1, the lower surface S2, and the edge surface E1 of the mask mother substrate MMSUB. The second inorganic material layer IL2L may cover the alignment mark AM. The second inorganic material layer IL2L may include an inorganic insulating material, and may have stress properties that are different from those of the first inorganic material layer IL1L. Redundant contents will be omitted.

Next, operation 1003 of FIG. 11, “forming a mask membrane by patterning the second inorganic film positioned on the upper surface of the mask substrate” will be described.

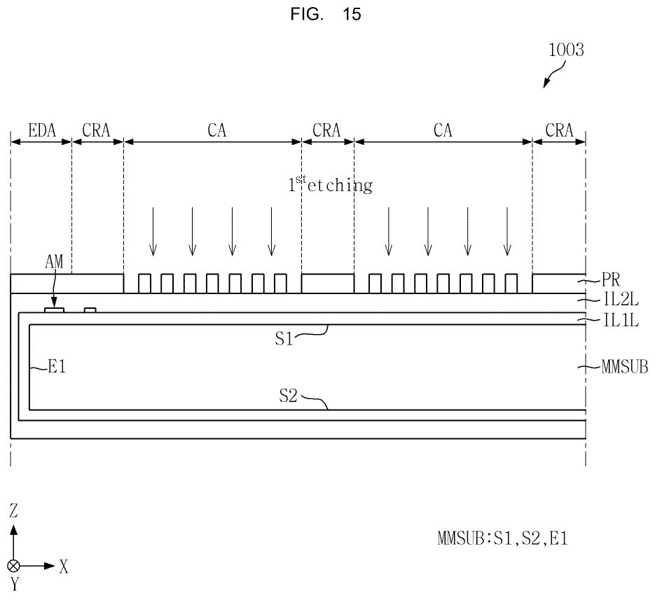

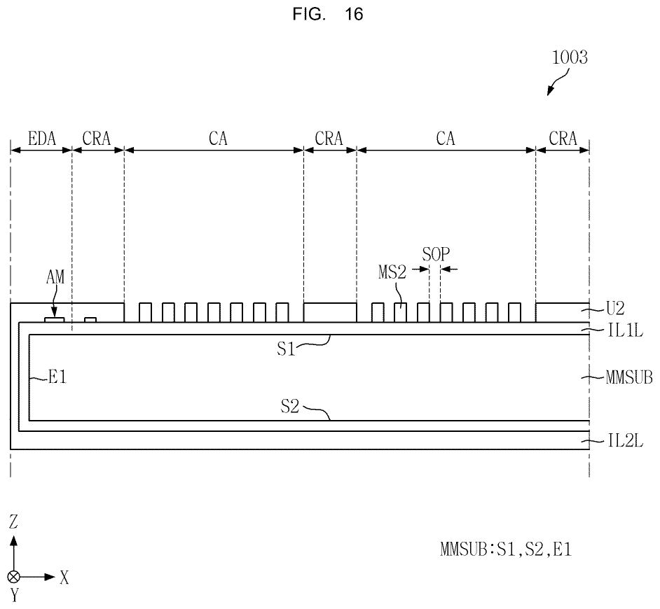

Referring to FIGS. 15 and 16, a plurality of photoresists PR are formed on the second inorganic material layer IL2L positioned on the upper surface S1 of the mask mother substrate MMSUB. In the present process, photoresists PR positioned in portions overlapping the cell peripheral area CRA and the edge area EDA may cover portions of the second inorganic material layer IL2L, and a plurality of photoresists PR positioned in portions overlapping the cell areas CA may be spaced apart from each other on the second inorganic material layer IL2L.

Next, a first etching process is performed using the plurality of photoresists PR as masks. As an example, the first etching process may be performed as a dry etching process. In the present process, a portion of the second inorganic material layer IL2L positioned in a portion where the photoresist PR is not formed may be removed. In the present process, the second inorganic material layer IL2L positioned on the upper surface S1 of the mask mother substrate MMSUB in the portions overlapping the cell area CA and the cell peripheral area CRA may be formed in the form of the second mask shadow MS2 and the second upper inorganic layer U2 illustrated in FIG. 8. The second mask shadows MS2 may surround the pixel opening SOP and may be spaced apart from each other, and the second mask shadow MS2 and the second upper inorganic layer U2 may be spaced apart from each other with the pixel opening SOP interposed therebetween.

In the present process, the second inorganic material layer IL2L may remain to entirely cover the edge surface E1 and the lower surface S2.

Next, operation 1005 of FIG. 11, “forming an opening by etching the first inorganic film and the second inorganic film in a rear direction of the mask substrate, and etching the silicon substrate overlapping the opening” will be described.

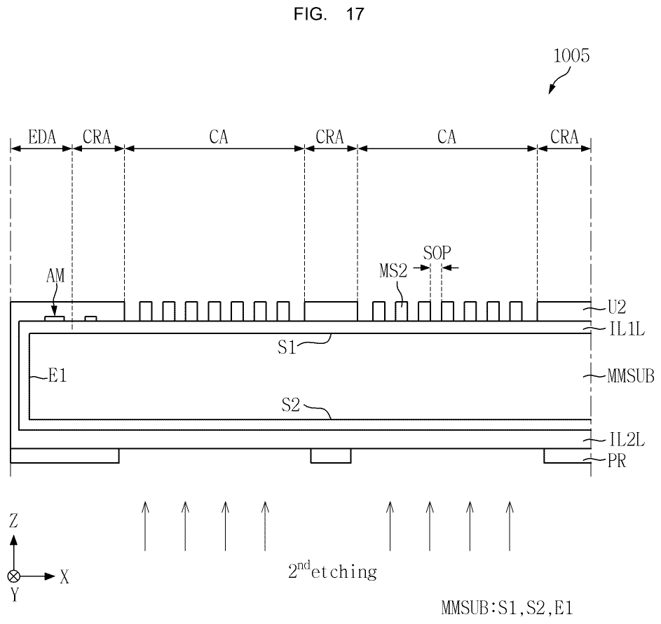

Referring to FIGS. 17 to 20, a plurality of photoresists PR are formed on the second inorganic material layer IL2L positioned on (e.g., below) the lower surface S2 of the mask mother substrate MMSUB. In the present process, the photoresists PR may be formed in portions overlapping the cell peripheral area CRA and the edge area EDA.

Next, a second etching process is performed using the plurality of photoresists PR as masks. The second etching process may be performed in a direction toward the lower surface S2 of the mask mother substrate MMSUB, that is, in a rear direction of the mask mother substrate MMSUB. As an example, the second etching process may be performed as a dry etching process.

In the present process, a portion of the first inorganic material layer IL1L and the second inorganic material layer IL2L positioned in a portion where the photoresist PR is not formed and positioned on the lower surface S2 of the mask mother substrate MMSUB may be removed. A temporary opening TOP may be formed in a portion where the first inorganic material layer IL1L and the second inorganic material layer IL2L are removed. The temporary opening TOP may be positioned in a portion overlapping the cell area CA.

Through the present process, portions of the first inorganic material layer IL1L and the second inorganic material layer IL2L positioned on the lower surface S2 of the mask mother substrate MMSUB may be formed in the form of the first lower inorganic layer L1 and the second lower inorganic layer L2 illustrated in FIG. 8. The first lower inorganic layer L1 and the second lower inorganic layer L2 may be positioned in a portion that overlaps the cell peripheral area CRA, and may not overlap the cell area CA.

Next, a plurality of photoresists PR are formed on the second lower inorganic layer L2 positioned in a portion overlapping the cell peripheral area CRA. Each photoresist PR may surround the temporary opening TOP.

It is illustrated in the drawing that only a portion of the second lower inorganic layer L2 positioned in the portion overlapping the edge area EDA is covered by the photoresist PR, but the present disclosure is not limited thereto. The second lower inorganic layer L2 positioned in the portion overlapping the edge area EDA may also be entirely covered by the photoresist PR.

Next, a third etching process is performed using the plurality of photoresists PR as masks. The third etching process may be performed in a direction toward the lower surface S2 of the mask mother substrate MMSUB, that is, in a rear direction of the mask mother substrate MMSUB. As an example, the third etching process may be performed as a wet etching process. In the present process, a portion of the mask mother substrate MMSUB positioned in a portion where the photoresist PR is not formed may be removed. In other words, a portion of the mask mother substrate MMSUB overlapping the temporary opening TOP may be removed.

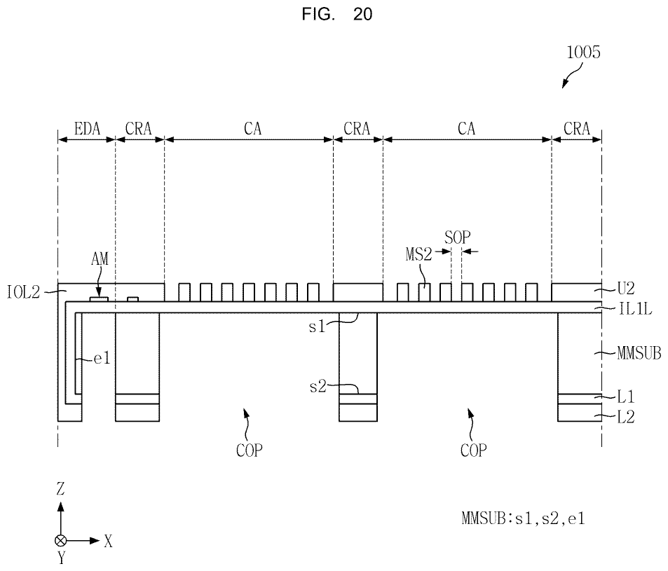

As illustrated in FIG. 20, through the present process, the mask mother substrate MMSUB may be positioned in portions that overlap the cell peripheral area CRA and the edge area EDA, and may not overlap the cell area CA. The mask mother substrate MMSUB may include an upper surface s1 and a lower surface s2 in a portion overlapping the cell peripheral area CRA, and may include an edge surface e1 in a portion overlapping the edge area EDA. The mask mother substrate MMSUB may define a mask opening COP, and the mask opening COP may be positioned in a portion overlapping the cell area CA.

In the present process, the second inorganic material layer IL2L may be formed in the form of the second mask inorganic layer IOL2 illustrated in FIG. 8.

Next, operation 1007 of FIG. 11, “reducing a thickness of the first inorganic film by etching a portion of the first inorganic film overlapping the opening in the rear direction of the mask substrate” will be described.

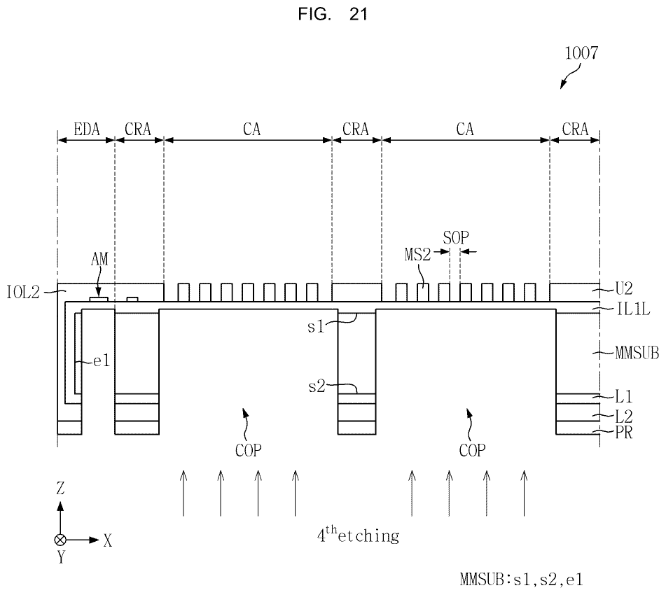

Referring to FIG. 21, a plurality of photoresists PR are formed on the second lower inorganic layer L2 overlapping the cell peripheral area CRA and the edge area EDA. Each photoresist PR may surround the mask opening COP.

Next, a fourth etching process is performed using the plurality of photoresists PR as masks. The fourth etching process may be performed in the rear direction of the mask mother substrate MMSUB. As an example, the fourth etching process may be performed as a wet etching process. In the present process, a height of the first inorganic material layer IL1L positioned in the portion overlapping the cell area CA in the third direction (Z-axis direction) may be reduced.

Next, operation 1009 of FIG. 11, “forming a pixel opening and a mask shadow by etching a portion of the first inorganic film overlapping the opening in the rear direction of the mask substrate” will be described.

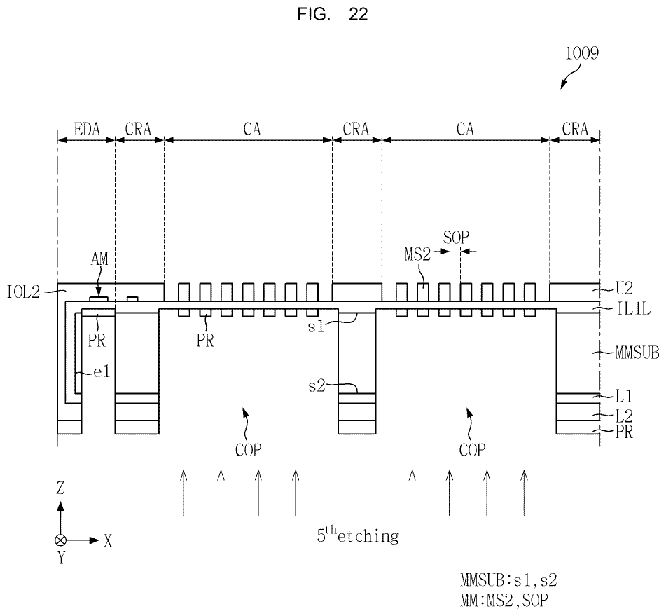

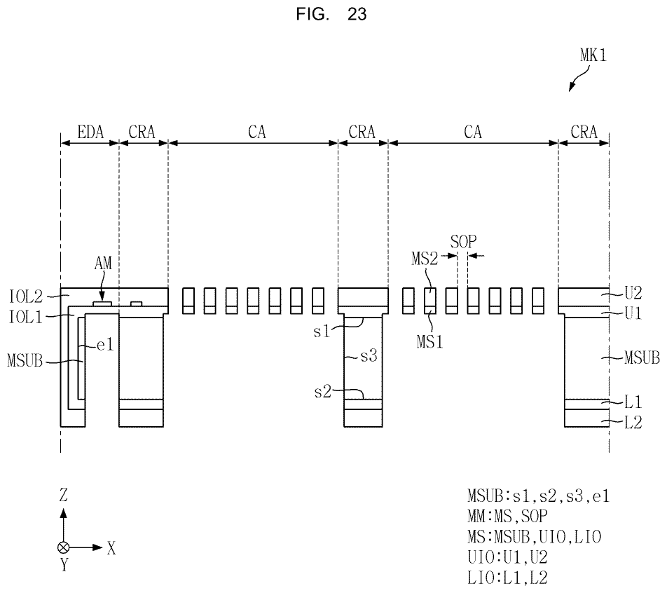

Referring to FIGS. 22 and 23, a plurality of photoresists PR are formed on the second lower inorganic layer L2 overlapping the cell peripheral area CRA and the edge area EDA. Each photoresist PR may surround the mask opening COP. Next, a plurality of photoresists PR are formed on the first inorganic material layer IL1L overlapping the cell area CA. The photoresists PR may be positioned toward the rear direction of the mask mother substrate MMSUB.

Next, a fifth etching process is performed using the plurality of photoresists PR as masks. The fifth etching process may be performed in the rear direction of the mask mother substrate MMSUB. As an example, the fifth etching process may be performed as a wet etching process. In the present process, a portion of the first inorganic material layer IL1L positioned in a portion where the photoresist PR is not formed may be entirely removed.

In the present process, the first inorganic material layer IL1L may be formed into the first upper inorganic layer U1, the first mask shadow MS1, and the first mask material layer IOL1 illustrated in FIG. 8, and the mask mother substrate MMSUB may be formed in the form of the mask substrate MSUB illustrated in FIG. 8. In the present process, the side surfaces of the first upper inorganic layer U1, the mask substrate MSUB, the first lower inorganic layer L1, and the second lower inorganic layer L2 facing the cell area CA may be more depressed in the first direction (X-axis direction) than the side surface of the second upper inorganic layer U2. This may be caused by the side surfaces of the first upper inorganic layer U1, the mask substrate MSUB, the first lower inorganic layer L1, and the second lower inorganic layer L2 facing the cell area CA being exposed by an etchant used in the fifth etching process.

Through the present process, a mask membrane MM positioned in a portion overlapping the cell area CA may be formed. The mask membrane MM may include a pixel opening SOP and a mask shadow MS. In the present process, the pixel opening SOP may be formed in the form illustrated in FIG. 8 while penetrating through the mask frame MF. As described above, the pixel opening SOP included in the mask according to one or more embodiments may be formed in a portion of the plurality of pixels SP illustrated in FIG. 5 overlapping the light-emitting layer IL. Therefore, the mask included in one or more embodiments may be used to manufacture the high-resolution display panel 410.

As a result, the mask MK1 illustrated in FIG. 8 may be formed. The mask MK1 may solve damage to the mask caused by stress imbalance between the inorganic layers positioned above and below the mask substrate MSUB by reducing the height of a portion of the upper inorganic layer UIO and the height of the mask shadow MS that are positioned above the mask substrate MSUB.

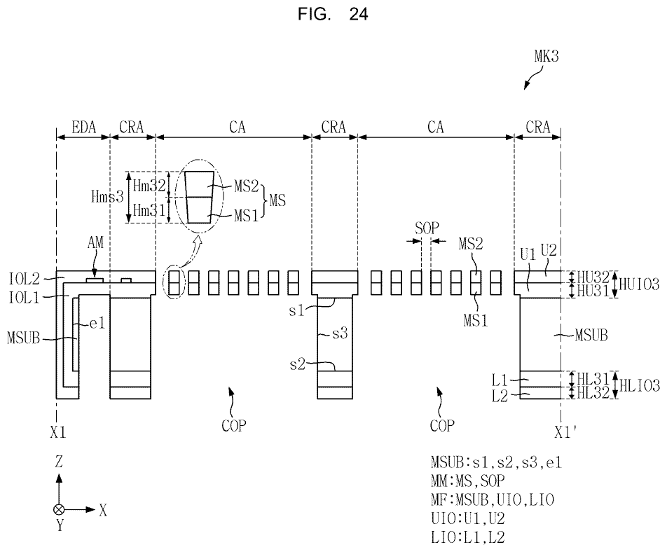

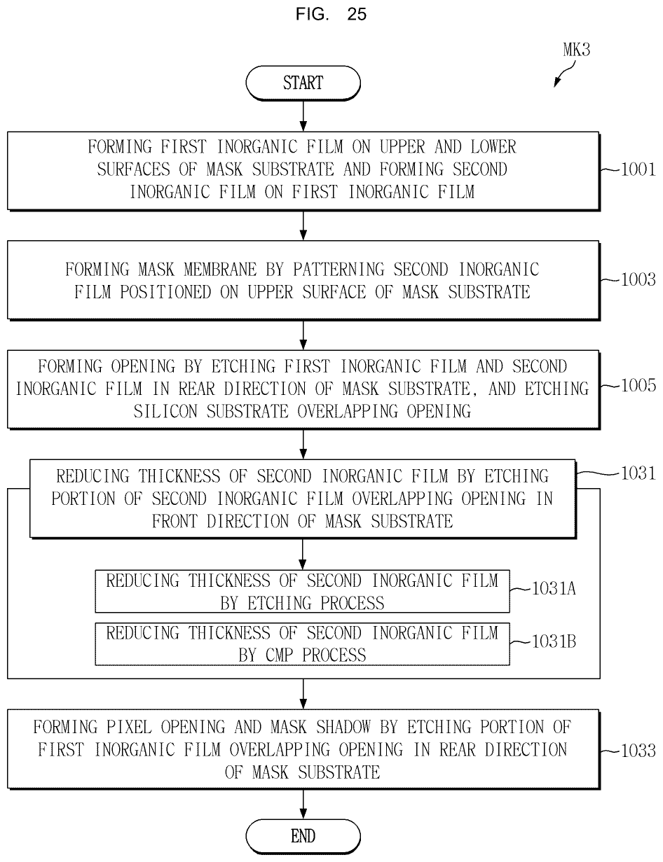

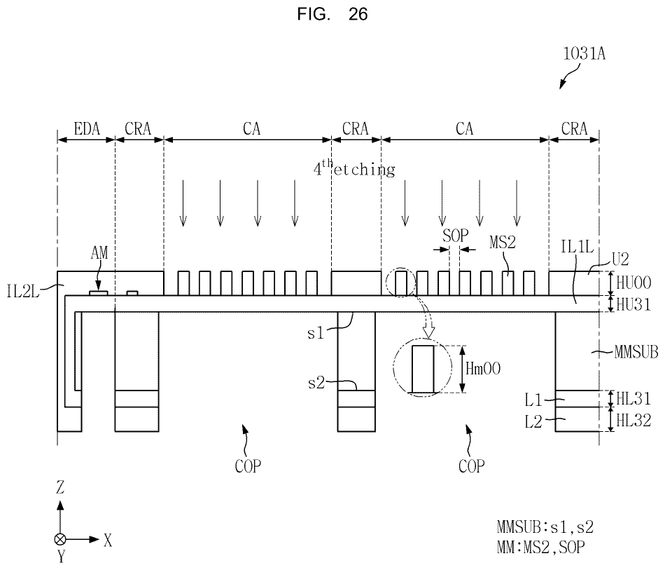

FIG. 24 is a cross-sectional view taken along the line X1-X1′ of FIG. 6, as still one or more other embodiments. FIG. 25 is a flowchart describing a method for manufacturing the mask illustrated in FIG. 24. FIGS. 26 to 30 are process cross-sectional views for describing the method for manufacturing the mask of FIG. 24.

Referring to FIG. 24, in a process of manufacturing a mask MK according to one or more embodiments, by performing an etching process or CMP process in a direction of the upper surface s1 of the mask substrate MSUB, a height HUIO3 of an upper inorganic layer UIO and a height Hms3 of a mask shadow MS that are positioned above the mask substrate MSUB may be less than a height HLIO3 of a lower inorganic layer LIO positioned below the mask substrate MSUB. Hereinafter, the commonalities between the mask MK1 and the mask MK3 will not be repeated, and the differences therebetween will be described later.

A first upper inorganic layer U1 of the mask MK3 may include the same thickness and material as a first lower inorganic layer L1 thereof. Therefore, the first upper inorganic layer U1 and the first lower inorganic layer L1 may include the same material, and a height HU31 of the first upper inorganic layer U1 and a height HL31 of the first lower inorganic layer L1 may be the same. In addition, the first upper inorganic layer U1 and the first lower inorganic layer L1 may include the same material as a first mask inorganic layer IOL1 positioned in a portion overlapping an edge area EDA of the mask MK3. Corresponding redundant descriptions will be omitted.

In some embodiments, the first upper inorganic layer U1 and the first mask shadow MS1 included in the mask MK3 may include the same thickness and material. Therefore, the height HU31 of the first upper inorganic layer U1 and the height Hm31 of the first mask shadow MS1 may be the same.

In some embodiments, a second upper inorganic layer U2 of the mask MK3 may include the same thickness and material as a second lower inorganic layer L2 thereof. However, a height HU32 of the second upper inorganic layer U2 and a height HL32 of the second lower inorganic layer L2 may be different.

In the process of manufacturing the mask MK3, the second upper inorganic layer U2 and the second lower inorganic layer L2 are formed to have the same height, and then through a subsequent process, the height HU32 of the second upper inorganic layer U2 may be less than the height HL32 of the second lower inorganic layer L2. The manufacturing process will be described later.

The second upper inorganic layer U2 and the second lower inorganic layer L2 may include the same material as a second mask inorganic layer IOL2 positioned in a portion overlapping the edge area EDA of the mask MK3.

In some embodiments, the second upper inorganic layer U2 and the second mask shadow MS2 included in the mask MK3 may include the same thickness and material. Therefore, the height HU32 of the second upper inorganic layer U2 and the height Hm32 of the second mask shadow MS2 may be the same.

In the mask MK3 according to one or more embodiments, the height HLIO3 of the lower inorganic layer LIO positioned below the mask substrate MSUB may have a greater value than the height HUIO3 of the upper inorganic layer UIO and the height Hms3 of the mask shadow MS that are positioned above the mask substrate MSUB. As a result, the mask MK3 may form stress of the inorganic layer positioned above the mask substrate MSUB similar to that of the inorganic layer positioned below the mask substrate MSUB. Therefore, the mask MK3 may solve damage to the mask caused by stress imbalance between the plurality of inorganic layers positioned above and below the mask substrate MSUB.

Hereinafter, a method for manufacturing the mask MK3 will be described with reference to FIGS. 25 to 30. The following description is only a portion of the processes of manufacturing the mask MK3, and processes for forming the components described with reference to the present document may be additionally performed before or after each operation. In addition, a process of manufacturing the mask known in the art may be additionally performed before or after each operation described below.

Operation 1001 of FIG. 25, “forming a first inorganic film on the upper and lower surfaces of the mask substrate and forming a second inorganic film on the first inorganic film,” operation 1003 thereof, “forming a mask membrane by patterning the second inorganic film positioned on the upper surface of the mask substrate,” and operation 1005 thereof, “forming an opening by etching the first inorganic film and the second inorganic film in a rear direction of the mask substrate, and etching the silicon substrate overlapping the opening” are the same as those of the method for manufacturing the mask MK1 illustrated in FIGS. 12 to 20. Therefore, the redundant description will be omitted, and the description will begin with “operation of reducing a thickness of the second inorganic film by etching a portion of the second inorganic film overlapping the opening in a front direction of the mask substrate”.

Referring to FIGS. 26 to 29, prior to performing the present process, a height HU31 of a first mask material layer IL1L included in the mask MK3 may be the same as a height HL31 of a first lower inorganic layer L1, and a height HU00 of a second upper inorganic layer U2 may be the same as a height HL32 of a second lower inorganic layer L2. In addition, a height Hm00 of a second mask shadow MS2 may be the same as the height HU00 of the second upper inorganic layer U2 and the height HL32 of the second lower inorganic layer L2.

Referring also to FIG. 25, the present process may be performed by performing either operation 1031A, “reducing a thickness of the second inorganic film by an etching process” or operation 1031B, “reducing a thickness of the second inorganic film by a CMP process”.

First, operation 1031A will be described with reference to FIG. 26. A fourth etching process of etching a portion of the second upper inorganic layer U2, the second mask shadow MS2, and the second inorganic material layer IL2L is performed. The fourth etching process may be performed in a direction the upper surface s1 of the mask mother substrate MMSUB. As an example, the fourth etching process may be performed as a wet etching process. Through the present process, the heights of the second upper inorganic layer U2, the second mask shadow MS2, and the second inorganic material layer IL2L may be entirely reduced.

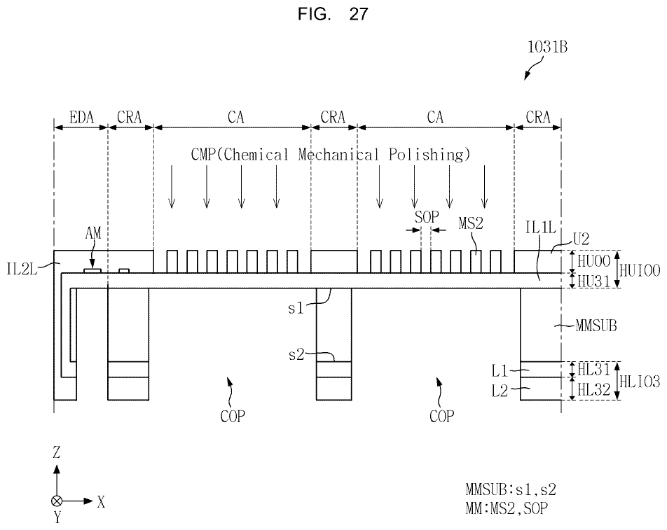

Next, operation 1031B will be described with reference to FIG. 27. A chemical mechanical polishing (CMP) process of physically removing a portion of the second upper inorganic layer U2, the second mask shadow MS2, and the second inorganic material layer IL2L is performed. The chemical mechanical polishing (CMP) refers to a process of polishing and flattening the surfaces of the second upper inorganic layer U2, the second mask shadow MS2, and the second inorganic material layer IL2L using chemical/mechanical elements. The chemical mechanical polishing (CMP) process may be performed in the direction of the upper surface s1 of the mask mother substrate MMSUB. Through the present process, the heights of the second upper inorganic layer U2, the second mask shadow MS2, and the second inorganic material layer IL2L may be entirely reduced.

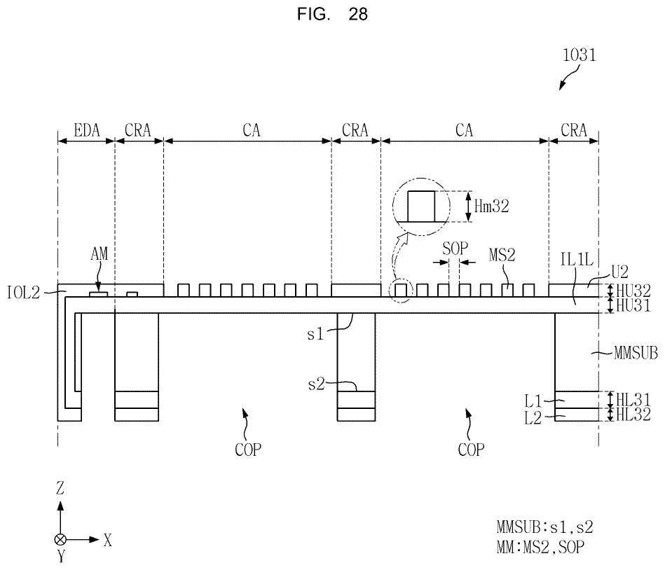

Referring to FIG. 28, through the present process, the height HU00 of the second upper inorganic layer U2 may have the height HU32 of the second upper inorganic layer U2 illustrated in FIG. 24, and the height Hm00 of the second mask shadow MS2 may have the height Hm32 of the second mask shadow MS2 illustrated in FIG. 24. For example, the height HU32 of the second upper inorganic layer U2 may be less than the height HU00 of the second upper inorganic layer U2, and the height Hm32 of the second mask shadow MS2 may be less than the height Hm00 of the second mask shadow MS2.

Next, operation 1033 of FIG. 25, “forming a pixel opening and a mask shadow by etching a portion of the first inorganic film overlapping the opening in the rear direction of the mask substrate” will be described.

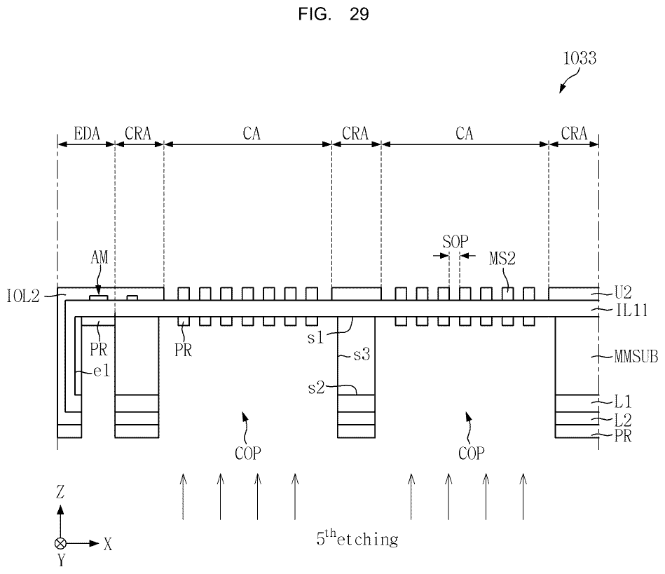

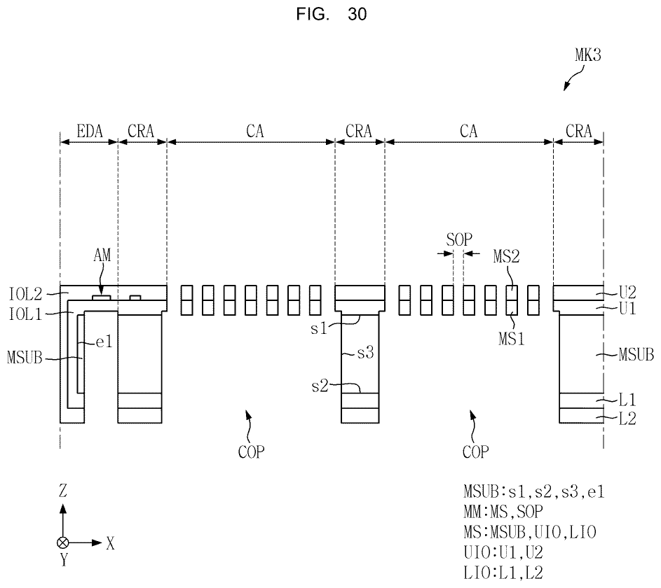

Referring to FIGS. 29 and 30, a plurality of photoresists PR are formed on the second lower inorganic layer L2 overlapping the cell peripheral area CRA and the edge area EDA. Each photoresist PR may surround the mask opening COP. Next, a plurality of photoresists PR are formed on the first inorganic material layer IL1L overlapping the cell area CA. The plurality of formed photoresists PR may be positioned toward the rear direction of the mask mother substrate MMSUB.

Next, a fifth etching process is performed using the plurality of photoresists PR as masks. The fifth etching process may be performed in the rear direction of the mask mother substrate MMSUB. As an example, the fifth etching process may be performed as a wet etching process. In the present process, a portion of the first inorganic material layer IL1L positioned in a portion where the photoresist PR is not formed may be entirely removed.

In the present process, the first inorganic material layer IL1L may be formed into the first upper inorganic layer U1, the first mask shadow MS1, and the first mask material layer IOL1 illustrated in FIG. 24, and the mask mother substrate MMSUB may be formed in the form of the mask substrate MSUB illustrated in FIG. 24. In the present process, the side surfaces of the first upper inorganic layer U1, the mask substrate MSUB, the first lower inorganic layer L1, and the second lower inorganic layer L2 facing the cell area CA may be more depressed in the first direction (X-axis direction) than the side surface of the second upper inorganic layer U2. Corresponding redundant descriptions will be omitted.

Through the present process, a mask membrane MM positioned in a portion overlapping the cell area CA may be formed. The mask membrane MM may include a pixel opening SOP and a mask shadow MS. In the present process, the pixel opening SOP may be formed in the form illustrated in FIG. 24 while penetrating through the mask frame MF.

As a result, the mask MK3 illustrated in FIG. 24 may be formed. The mask MK3 may solve damage to the mask caused by stress imbalance between the inorganic layers positioned above and below the mask substrate MSUB by reducing the height of a portion of the upper inorganic layer UIO and the height of the mask shadow MS that are positioned above the mask substrate MSUB.

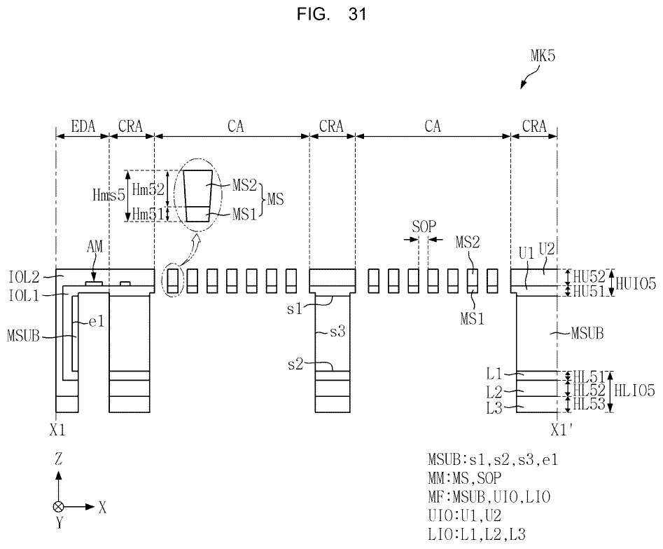

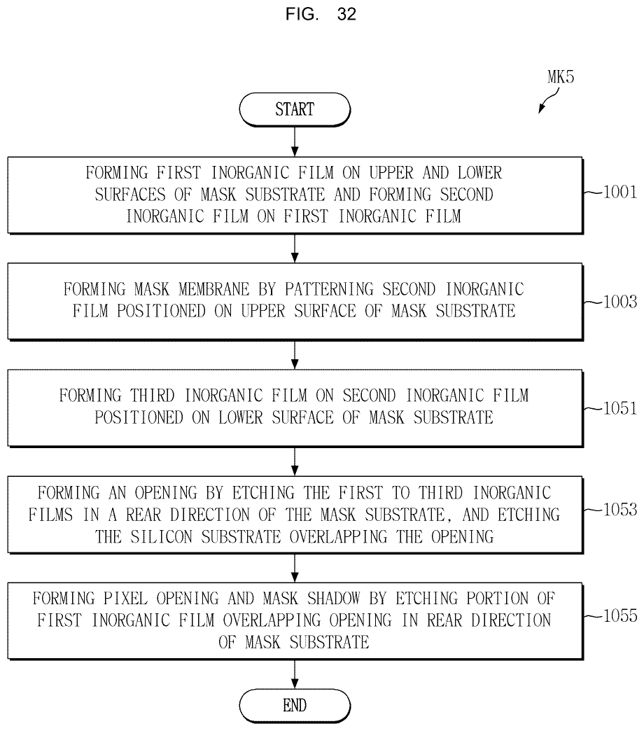

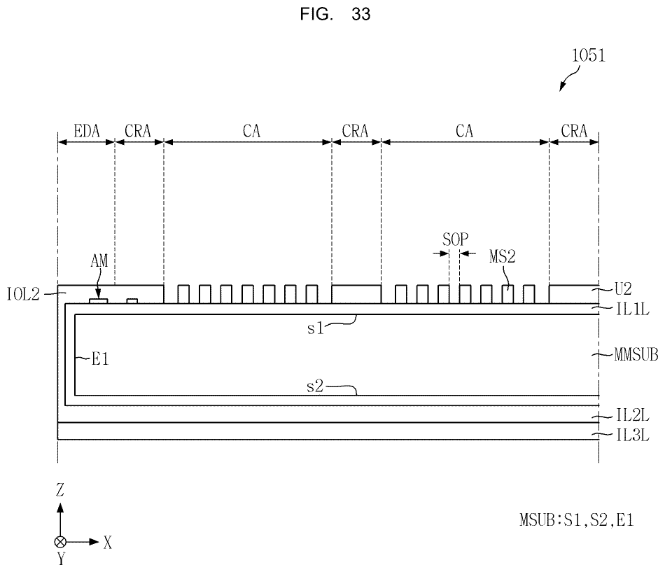

FIG. 31 is a cross-sectional view taken along the line X1-X1′ of FIG. 6, as still one or more other embodiments. FIG. 32 is a flowchart describing a method for manufacturing the mask illustrated in FIG. 31. FIGS. 33 to 36 are process cross-sectional views for describing the method for manufacturing the mask of FIG. 31.

A mask in which a thickness of a upper inorganic layer included in the mask is thinner than a thickness of a lower inorganic layer by additionally forming a third lower inorganic layer on the second lower inorganic layer positioned below the mask substrate in the process of manufacturing the mask, and a process of manufacturing the mask will be described with reference to FIGS. 31 to 36. Hereinafter, the commonalities between the mask MK1 and a mask MK5 will not be repeated, and the differences between the mask MK1 and the mask MK5 will be described.

Referring to FIG. 31, a mask frame MF included in a mask MK5 according to one or more embodiments may include a mask substrate MSUB, an upper inorganic layer UIO, and a lower inorganic layer LIO. The upper inorganic layer UIO of the mask MK5 may include a first upper inorganic layer U1 and a second upper inorganic layer U2, and the lower inorganic layer LIO of the mask MK5 may include a first lower inorganic layer L1, a second lower inorganic layer L2, and a third lower inorganic layer L3.

The first upper inorganic layer U1 of the mask MK5 may include the same material as the first lower inorganic layer L1 thereof. In addition, the first upper inorganic layer U1 and the first lower inorganic layer L1 may include the same material as a first mask inorganic layer IOL1 positioned in a portion overlapping an edge area EDA of the mask MK5. Corresponding redundant descriptions will be omitted.

In some embodiments, a height HU51 of the first upper inorganic layer U1 and a height HL51 of the first lower inorganic layer L1 included in the mask MK5 may be the same, and the height HU51 of the first upper inorganic layer U1 and a height Hm51 of the first mask shadow MS1 may be the same.

The second upper inorganic layer U2 of the mask MK5 may include the same material as the second lower inorganic layer L2 thereof. In addition, the second upper inorganic layer U2 and the second lower inorganic layer L2 may include the same material as a second mask inorganic layer IOL2 positioned in a portion overlapping an edge area EDA of the mask MK5. Corresponding redundant descriptions will be omitted.

In some embodiments, a height HU52 of the second upper inorganic layer U2 and a height HL52 of the second lower inorganic layer L2 included in the mask MK5 may be the same, and the height HU52 of the second upper inorganic layer U2 and a height Hm52 of the second mask shadow MS2 may be the same.

The third lower inorganic layer L3 of the mask MK5 may be positioned on the second lower inorganic layer L2, and may be in contact with the second lower inorganic layer L2. The third lower inorganic layer L3 may include an inorganic insulating material, for example, silicon nitride, but is not limited thereto.

In some embodiments, because the lower inorganic layer LIO of the mask MK5 includes the third lower inorganic layer L3, a height HLIO5 of the lower inorganic layer LIO may be greater than a height HUIO5 of the upper inorganic layer UIO by a height HL53 of the third lower inorganic layer L3.

Therefore, the mask MK5 may solve damage to the mask caused by stress imbalance between the plurality of inorganic layers positioned above and below the mask substrate MSUB by forming the height HLIO5 of the lower inorganic layer LIO positioned below the mask substrate MSUB to have a greater value than the height HUIO5 of the upper inorganic layer UIO or the height Hms5 of the mask shadow MS that are positioned above the mask substrate MSUB. The height HUIO5 of the upper inorganic layer UIO of the mask MK5 and the height Hms5 of the mask shadow MS may be the same. The manufacturing process will be described later.

Hereinafter, a method for manufacturing the mask MK5 according to one or more embodiments will be described with reference to FIGS. 32 to 36. The following description is only a portion of the processes of manufacturing the mask MK5, and processes for forming the components described with reference to the present document may be additionally performed before or after each operation. In addition, a process of manufacturing the mask known in the art may be additionally performed before or after each operation described below.

Operation 1001 of FIG. 32, “forming a first inorganic film on the upper and lower surfaces of the mask substrate and forming a second inorganic film on the first inorganic film” and operation 1003 thereof, “forming a mask membrane by patterning the second inorganic film positioned on the upper surface of the mask substrate” are the same as those of the method for manufacturing the mask MK1 illustrated in FIGS. 12 to 16.

Therefore, the redundant description will be omitted, and the description will begin with operation 1051 of FIG. 32, “forming a third inorganic film on the second inorganic layer positioned on the lower surface of the mask substrate”.

Referring to FIG. 33, a third inorganic material layer IL3L is formed on the second inorganic material layer IL2L positioned on the lower surface S2 of the mask mother substrate MMSUB. Unlike the first inorganic material layer IL1L and the second inorganic material layer IL2L, the third inorganic material layer IL3L may be formed only on the second inorganic material layer IL2L positioned on the lower surface S2 of the mask mother substrate MMSUB. That is, the third inorganic material layer IL3L may entirely cover only the lower surface S2 of the mask mother substrate MMSUB.

Next, operation 1053 of FIG. 32, “forming an opening by etching the first to third inorganic films in a rear direction of the mask substrate, and etching the silicon substrate overlapping the opening” will be described.

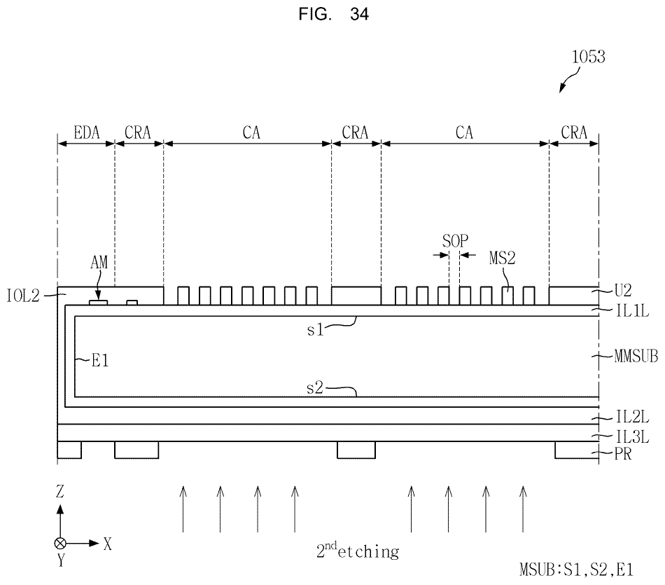

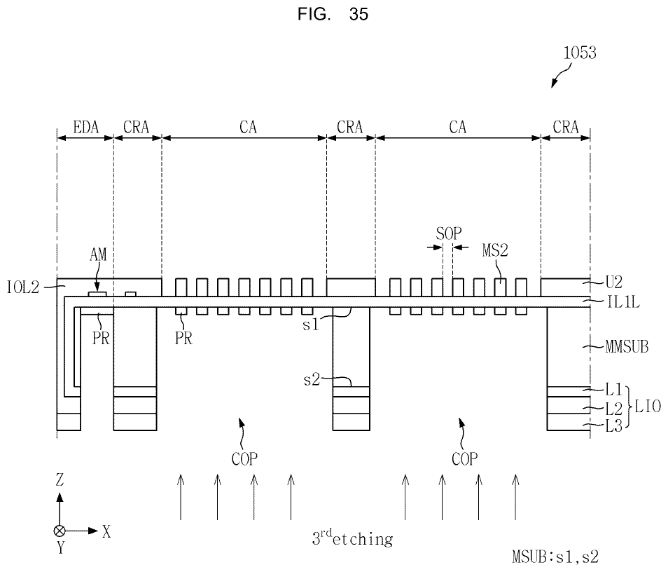

Referring to FIGS. 34 and 35, a plurality of photoresists PR are formed on the third inorganic material layer IL3L positioned on the lower surface S2 of the mask mother substrate MMSUB. In the present process, the photoresists PR may be formed in portions overlapping the cell peripheral area CRA and the edge area EDA.

Next, a second etching process is performed using the plurality of photoresists PR as masks. The second etching process may be performed in a direction toward the lower surface S2 of the mask mother substrate MMSUB, that is, in a rear direction of the mask mother substrate MMSUB. As an example, the second etching process may be performed as a dry etching process.

In the present process, a portion of the first inorganic material layer IL1L, the second inorganic material layer IL2L, and the third inorganic material layer IL3L positioned in a portion where the photoresist PR is not formed and positioned on the lower surface S2 of the mask mother substrate MMSUB may be removed.

Next, a portion of the mask mother substrate MMSUB positioned in a portion where the photoresist PR is not formed is removed. In the present process, the mask mother substrate MMSUB may be positioned in a portion that overlaps the cell peripheral area CRA and the edge area EDA, and may not overlap the cell area CA. The mask mother substrate MMSUB may include an upper surface s1 and a lower surface s2 in a portion overlapping the cell peripheral area CRA, and may include an edge surface e1 in a portion overlapping the edge area EDA. The mask mother substrate MMSUB positioned in a portion overlapping the cell peripheral area CRA may define a mask opening COP.

In the present process, the first inorganic material layer IL1L, the second inorganic material layer IL2L, and the third inorganic material layer IL3L may be formed in the form of the first lower inorganic layer L1, the second lower inorganic layer L2, and the third lower inorganic layer L3 illustrated in FIG. 31. That is, in the present process, the lower inorganic layer LIO illustrated in FIG. 31 may be formed. The lower inorganic layer LIO may surround the mask opening COP.

Next, operation 1055 of FIG. 32, “forming a pixel opening and a mask shadow by etching a portion of the first inorganic film overlapping the opening in the rear direction of the mask substrate” will be described.

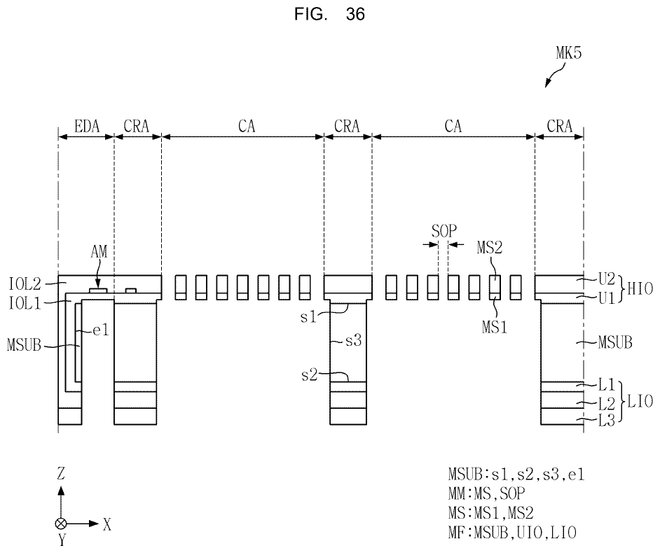

Referring to FIGS. 35 and 36, a plurality of photoresists PR are formed on the third inorganic material layer IL3L positioned on the lower surface S2 of the mask mother substrate MMSUB. In the present process, the photoresists PR may be formed in portions overlapping the cell peripheral area CRA and the edge area EDA. In addition, a plurality of photoresists PR are formed on the first inorganic material layer IL1L overlapping the cell area CA. The plurality of formed photoresists PR may be positioned toward the rear direction of the mask mother substrate MMSUB.

Next, a third etching process is performed using the plurality of photoresists PR as masks. The third etching process may be performed in the rear direction of the mask mother substrate MMSUB. As an example, the third etching process may be performed as a wet etching process. In the present process, a portion of the first inorganic material layer IL1L positioned in a portion where the photoresist PR is not formed may be entirely removed.

In the present process, the first inorganic material layer IL1L may be formed into the first upper inorganic layer U1, the first mask shadow MS1, and the first mask material layer IOL1 illustrated in FIG. 31, and the mask mother substrate MMSUB may be formed in the form of the mask substrate MSUB illustrated in FIG. 31. In the present process, the side surfaces of the first upper inorganic layer U1, the mask substrate MSUB, the first lower inorganic layer L1, and the second lower inorganic layer L2 facing the cell area CA may be more depressed in the first direction (X-axis direction) than the side surface of the second upper inorganic layer U2. Corresponding redundant descriptions will be omitted.

In addition, through the present process, a mask membrane MM positioned in a portion overlapping the cell area CA may be formed. The mask membrane MM may include a pixel opening SOP and a mask shadow MS. In the present process, the pixel opening SOP may be formed in the form illustrated in FIG. 31 while penetrating through the mask frame MF. As described above, the pixel opening SOP included in the mask may be formed in a portion of the plurality of pixels SP illustrated in FIG. 5 overlapping the light-emitting layer IL. Therefore, the mask included in one or more embodiments may be used to manufacture the high-resolution display panel 410.

As a result, the mask MK5 illustrated in FIG. 31 may be formed. The mask MK5 may solve damage to the mask caused stress imbalance between the inorganic layers positioned above and below the mask substrate MSUB by increasing the height of the lower inorganic layer LIO positioned below the mask substrate MSUB.

It should be understood that embodiments described herein should be considered in a descriptive sense and not for purposes of limitation. Descriptions of aspects within each embodiment should typically be considered as available for other similar aspects in other embodiments. While one or more embodiments have been described with reference to the figures, it will be understood by those of ordinary skill in the art that various changes in form and details may be made therein without departing from the spirit and scope as defined by the following claims and equivalents thereof.

What is claimed is:

1. A deposition mask comprising:
a mask substrate comprising a plurality of cell areas, and a cell peripheral area surrounding the cell areas in plan view;
a mask membrane overlapping the cell area of the mask substrate, defining a pixel opening, and comprising a mask shadow; and
a mask frame overlapping the cell peripheral area, and comprising an upper inorganic layer above an upper surface of the mask substrate, and a lower inorganic layer below a lower surface of the mask substrate and having a height that is different than a height of the upper inorganic layer and that is greater than a height of the mask shadow.

2. The deposition mask of claim 1, wherein the upper inorganic layer comprises a first upper inorganic layer in contact with the upper surface of the mask substrate, and a second upper inorganic layer above the first upper inorganic layer, and
wherein the lower inorganic layer comprises a first lower inorganic layer in contact with the lower surface of the mask substrate, and a second lower inorganic layer below the first lower inorganic layer.

3. The deposition mask of claim 2, wherein the first upper inorganic layer and the first lower inorganic layer comprise a same material, and
wherein the second upper inorganic layer and the second lower inorganic layer comprise a same material.

4. The deposition mask of claim 3, wherein the first upper inorganic layer and the first lower inorganic layer comprise different respective materials.

5. The deposition mask of claim 4, wherein the first upper inorganic layer and the first lower inorganic layer comprise different respective stress properties.

6. The deposition mask of claim 2, wherein the mask shadow comprises a first mask shadow comprising a same material as the first upper inorganic layer, and a second mask shadow comprising a same material as the second upper inorganic layer.

7. The deposition mask of claim 6, wherein the first mask shadow comprises a same material as the first lower inorganic layer, and
wherein the second mask shadow comprises a same material as the second lower inorganic layer.

8. The deposition mask of claim 7, wherein a height of the first mask shadow is less than a height of the first lower inorganic layer.

9. The deposition mask of claim 7, wherein a height of the second mask shadow is substantially equal to a height of the second upper inorganic layer, and
wherein the height of the second mask shadow is less than a height of the second lower inorganic layer.

10. The deposition mask of claim 6, wherein the first mask shadow comprises a first surface in a direction away from the second mask shadow,
wherein the second mask shadow comprises a second surface in a direction away from the first mask shadow, and
wherein a width of the first surface in a direction parallel to the mask substrate is less than a width of the second surface.

11. The deposition mask of claim 2, wherein the first upper inorganic layer comprises a first portion and a second portion, and
wherein a height of the first portion is greater than a height of the second portion.

12. The deposition mask of claim 1, wherein the mask substrate comprises silicon, and has a circular shape in plan view.

13. The deposition mask of claim 1, wherein the mask shadow completely surrounds the pixel opening in plan view, and
wherein the mask frame completely surrounds the mask shadow in plan view.

14. The deposition mask of claim 3, wherein the mask substrate comprises an edge surface comprising an edge of the mask substrate, connecting the upper surface of the mask substrate and the lower surface of the mask substrate, being entirely covered by the first upper inorganic layer, and contacting the first upper inorganic layer.

15. The deposition mask of claim 14, wherein the edge surface is entirely covered by the second upper inorganic layer.

16. The deposition mask of claim 3, wherein the lower inorganic layer further comprises a third lower inorganic layer below the second lower inorganic layer.

17. A method for manufacturing a deposition mask, the method comprising:
forming a first inorganic material layer on a mask substrate;
forming a second inorganic material layer on the first inorganic material layer;
forming a mask membrane by patterning the second inorganic material layer above an upper surface of the mask substrate;
forming an opening by removing the first inorganic material layer and the second inorganic material layer below a lower surface of the mask substrate, and by removing a portion of the mask substrate;
reducing a height of the first inorganic material layer by etching a portion of the first inorganic material layer overlapping the opening; and
forming a pixel opening and a mask shadow.

18. The method of claim 17, wherein the forming of the first inorganic material layer comprises concurrently forming the first inorganic material layer respectively above and below the upper and lower surfaces of the mask substrate, and
wherein the forming of the second inorganic material layer comprises concurrently forming the second inorganic material layer respectively above and below the upper and lower surfaces of the mask substrate.

19. The method of claim 18, wherein the etching of the portion of the first inorganic material layer is performed in a rear direction of the mask substrate.

20. The method of claim 19, wherein, in the forming of the mask shadow, the mask shadow comprises a first mask shadow comprising a same material as the first inorganic material layer, and a second mask shadow comprising a same material as the second inorganic material layer, and
wherein a height of the first mask shadow is less than a height of the first inorganic material layer below the lower surface of the mask substrate.

21. An electronic device comprising:
A display device including a display panel formed using a deposition mask;
the mask substrate comprising a plurality of cell areas, and a cell peripheral area surrounding the cell areas in plan view;
a mask membrane overlapping the cell area of the mask substrate, defining a pixel opening, and comprising a mask shadow; and
a mask frame overlapping the cell peripheral area, and comprising an upper inorganic layer above an upper surface of the mask substrate, and a lower inorganic layer below a lower surface of the mask substrate and having a height that is different than a height of the upper inorganic layer and that is greater than a height of the mask shadow.
